(19) United States
(12) Patent Application Publication
(10) Pub. No.: US 2025/0369265 A1
(43) Pub. Date: Dec. 4, 2025

(54) MONITORING DEVICE, MONITORING METHOD, AND PROGRAM

(71) Applicant: FUJI ELECTRIC CO., LTD., Kanagawa (JP)

(72) Inventor: Shinji YUKAWA, Mie (JP)

(21) Appl. No.: 19/188,562

(22) Filed: Apr. 24, 2025

(30) Foreign Application Priority Data
Jun. 4, 2024 (JP) 2024-090781

(51) Int. Cl. E05B 81/74; B61D 19/00; E05B 81/08; E05B 81/28; G01R 27/26

(52) U.S. Cl. CPC E05B 81/74; E05B 81/08; E05B 81/28; G01R 27/2611; B61D 19/005

(57) ABSTRACT

A monitoring device for monitoring a state of a locking device, the locking device includes a first member, a second member configured to achieve a locked state of a door of a railway vehicle by establishing a predetermined positional relation with the first member upon a movement toward the first member, and a solenoid configured to move the second member in a first direction away from the first member, wherein the monitoring device is configured to monitor the state of the locking device based on an electrical state observed when a first coil of the solenoid is energized.

The present application is based on and claims priority to Japanese patent application no. 2024-090781 filed on Jun. 4, 2024, with the Japanese Patent Office, the entire contents of which are hereby incorporated by reference.

### BACKGROUND OF THE INVENTION

### 1. Field of the Invention

The disclosures herein relate to monitoring devices, monitoring methods, and programs.

### 2. Description of the Related Art

In related arts, there has been known a method for monitoring states of a locking device for locking and unlocking a door of a railway vehicle by outputs of a limit switch (see, e.g., Patent Literature (PTL) 1).

However, in the method described above, only two states of the limit switch, ON and OFF, can be utilized. Therefore, there may be a case where the state of the locking device cannot be properly monitored.

In view of the above problem, it is an object of the present invention to provide a technology capable of monitoring the states the locking device for locking and unlocking the door of the railway vehicle.

### CITATION LIST

### Patent Literature

[PTL 1] Japanese Patent Laid-Open Publication No. 2022-149880

### SUMMARY OF THE INVENTION

A monitoring device for monitoring a state of a locking device, the locking device includes a first member, a second member configured to achieve a locked state of a door of a railway vehicle by establishing a predetermined positional relation with the first member upon a movement toward the first member, and a solenoid configured to move the second member in a first direction away from the first member, wherein the monitoring device is configured to monitor the state of the locking device based on an electrical state observed when a first coil of the solenoid is energized.

A monitoring method for monitoring a state of a locking device includes a first member, a second member configured to achieve a locked state of a door of a railway vehicle by establishing a predetermined positional relation with the first member upon a movement toward the first member, and a solenoid configured to move the second member in a first e t direction away from the first member, wherein a monitoring device is configured to monitor the state of the locking device based on an electrical state observed when a first coil of the solenoid is energized.

A computer readable medium stores a program that causes an information processing device to execute a process to monitor a state of a locking device includes a first member, a second member configured to achieve a locked state of a door of a railway vehicle by establishing a predetermined positional relation with the first member upon a movement toward the first member, and a solenoid configured to move the second member in a first direction away from the first member, wherein a monitoring device is configured to monitor the state of the locking device based on an electrical state observed when a first coil of the solenoid is energized.

According to the above embodiments, it is possible to monitor the states of the locking device for locking and unlocking the door of the railway vehicle.

### BRIEF DESCRIPTION OF THE DRAWINGS

FIG. 1 is a block diagram illustrating an example of a configuration for controlling and monitoring a door of a railway vehicle;

FIG. 2 is a drawing illustrating a first example of a door locking device;

FIG. 3 is a drawing illustrating the first example of the door locking device;

FIG. 4 is a drawing illustrating a first example of a driving circuit for the locking device;

FIG. 5 is a time chart illustrating a first example of a method for monitoring the state of the locking device;

FIG. 6 is a functional block diagram illustrating a first example of a configuration related to a function for monitoring the state of the locking device;

FIG. 7 is a drawing illustrating an example of a correlation between a plunger protrusion and a solenoid coil inductance, and a first example of a monitoring reference for the plunger protrusion;

FIG. 8 is a flowchart schematically illustrating a first example of control processing of a door control device;

FIG. 9 is a time chart describing a second example of a method for monitoring the state of the locking device;

FIG. 10 is a functional block diagram illustrating a second example of a configuration related to a function for monitoring the state of the locking device;

FIG. 11 is a drawing illustrating an example of the correlation between the plunger protrusion and the solenoid coil inductance, and a second example of a monitoring reference for the plunger protrusion;

FIG. 12 is a drawing illustrating an example of a state at the time of completion of a locking operation of the locking device when the locking device is abnormal;

FIG. 13 is a time chart describing an example of the locking operation of the locking device when the locking device is abnormal;

FIG. 14 is a drawing illustrating another example of a state at the time of completion of the locking operation of the locking device when the locking device is abnormal;

FIG. 15 is a time chart explaining another example of the locking operation of the locking device when the locking device is abnormal;

FIG. 16 is a drawing illustrating yet another example of a state at the time of completion of the locking operation of the locking device when the locking device is abnormal;

FIG. 17 is a time chart explaining yet another example of the locking operation of the locking device when the locking device is abnormal;

FIG. 18 is a flowchart schematically illustrating a second example of control processing of a door control device;

FIG. 19 is a drawing illustrating a second example of the door locking device;

FIG. 20 is a drawing illustrating the second example of the door locking device;

FIG. 21 is a drawing illustrating a second example of the driving circuit for the locking device;

FIG. 22 is a time chart describing a third example of a method for monitoring the state of the locking device;

FIG. 23 is a drawing illustrating an example of the correlation between the plunger protrusion and a locking solenoid coil inductance;

FIG. 24 is a flowchart schematically illustrating a third example of control processing of a door control device;

FIG. 25 is a time chart describing a fourth example of a method for monitoring the state of the locking device;

FIG. 26 is a flowchart schematically illustrating a fourth example of control processing of a door control device;

FIG. 27 is a drawing illustrating a third example of the door locking device; and

FIG. 28 is a drawing illustrating the third example of the door locking device.

### DESCRIPTION OF THE PREFERRED EMBODIMENTS

In the following, embodiments of the present invention will be described with reference to the accompanying drawings.

### [Configuration for Door Control of Railway Vehicle]

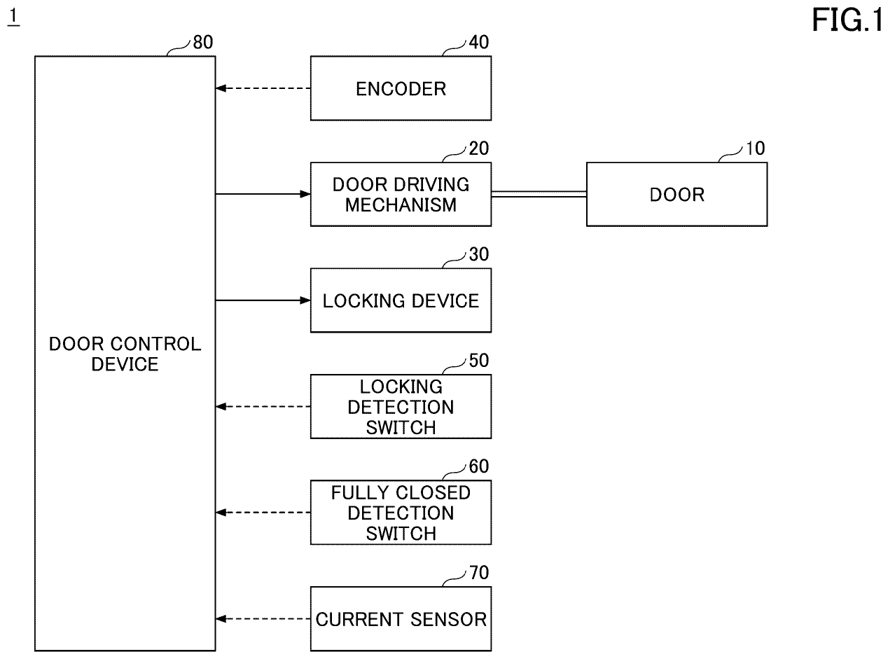

A configuration for control and monitoring of a door 10 of a railway vehicle 1 according to the present embodiment will be described with reference to FIG. 1.

FIG. 1 is a block diagram illustrating an example of a configuration for controlling and monitoring the door 10 of a railway vehicle 1.

As shown in FIG. 1, the railway vehicle 1 includes the door 10, a door driving mechanism 20, a locking device 30, an encoder 40, a locking detection switch 50, a fully closed detection switch 60, a current sensor 70, and a door control device 80.

The railway vehicle 1 may have one car, or a plurality of cars joined in a row.

The door 10 is provided at an opening (hereinafter, for convenience, referred to as “door opening”) on a lateral surface of a vehicle body of the railway vehicle 1. The door 10 is, for example, a double sliding door.

The door driving mechanism 20 mechanically drives the door 10 in the opening and closing directions. The door driving mechanism 20 is provided, for example, above the door opening inside the vehicle body of the railway vehicle 1. The door driving mechanism 20 includes, for example, an electric motor, and uses the electric motor as a power source to drive the door 10 in the opening and closing directions. The electric motor may be a rotary motor (e.g., motor 22, described below) or a linear motor.

Operation of the door driving mechanism 20 is controlled by the door control device 80. For example, the door driving mechanism 20 is electrically driven by electric power supplied from the door control device 80.

The locking device 30 locks and unlocks the door 10. Like the door driving mechanism 20, for example, the locking device 30 is provided above the door opening inside the vehicle body of the railway vehicle 1.

Operation of the door locking device 30 is controlled by the door control device 80. For example, it is electrically driven by electric power supplied from the door control device 80.

The encoder 40 outputs detection information related to a position of the door 10. For example, the encoder 40 detects a rotational position and rotational speed of the rotary motor included in the door driving mechanism 20 and a displacement position of a moving element of the linear motor, and outputs detection information. The detection information of the encoder 40 is received into the door control device 80.

The locking detection switch 50 is a momentary switch for detecting the locking state of the door 10 by the locking device 30. The locking detection switch 50 is, for example, directly or indirectly attached to the vehicle body of the railway vehicle 1. When the door 10 is locked by the locking device 30, the locking detection switch 50 is turned ON by mechanically pressing an actuator part by a predetermined member of the locking device 30. Conversely, when the door 10 is not locked by the locking device 30, that is, when it is unlocked, pressing of the actuator part by the member is released, and the locking detection switch 50 is turned OFF. The detection signal indicating ON or OFF of the locking detection switch 50 (i.e., ON signal or OFF signal) is received into the door control device 80. Thus, when the detection signal of the locking detection switch 50 is an ON signal, the door control device 80 can determine that the door 10 is locked by the locking device 30, and when the detection signal of the locking detection switch 50 is an OFF signal, the door control device 80 can determine that the door 10 is unlocked.

The fully closed detection switch 60 is a momentary switch for detecting the fully closed state of the door 10. The fully closed detection switch 60 is, for example, attached directly or indirectly to the vehicle body of the railway vehicle 1. When the door 10 is in the fully closed state, the fully closed detection switch 60 is turned on by mechanically pressing the actuator part by a member interlocking with the opening and closing operation of the door 10. Conversely, when the door 10 is not in the fully closed state, the fully closed detection switch 60 is turned off by releasing the pressing of the actuator part by the member. The detection signal indicating ON or OFF of the fully closed detection switch 60 (i.e., ON signal or OFF signal) is received into the door control device 80. Thus, when the detection signal of the fully closed detection switch 60 is an ON signal, the door 10 is in the fully closed state, and when the detection signal of the fully closed detection switch 60 is an OFF signal, the door control device 80 can determine that the door 10 is not in the fully closed state, that is, the door 10 is in an open state.

The current sensor 70 detects the current of the solenoid 34 included in the locking device 30.

The detected signal of the current sensor 70 is received into the door control device 80.

The door control device 80 controls an operation of the door 10.

Specifically, the door control device 80 controls the operation of the door 10 by electrically driving the door driving mechanism 20 along a sequence of opening or closing operation of the door 10. For example, the door control device 80 incorporates a power conversion device that converts a direct current supplied from a predetermined power source of the railway vehicle 1 into a three-phase alternating current of a predetermined voltage and a predetermined frequency, and controls the power conversion device to supply driving power to the door driving mechanism 20. The power conversion device may be located outside the door control device 80.

The door control device 80 controls the locking and unlocking of the door 10 by electrically driving the locking device 30 according to the sequence of the opening or closing operation of the door 10.

The function of the door control device 80 can be achieved by, for example, optional hardware or combinations of optional hardware and software. For example, the door control device 80 is mainly composed of a computer including a CPU (Central Processing Unit), a memory device, an auxiliary storage device, and an interface device for input and output with the outside.

### First Example of Locking Device

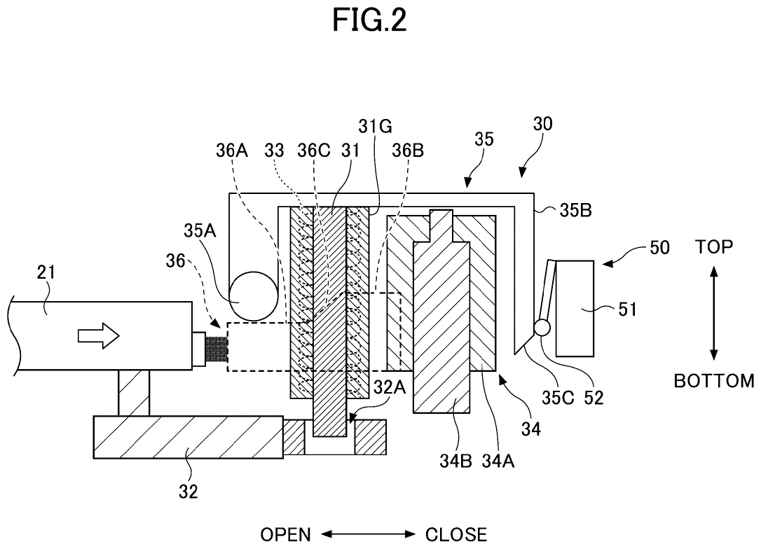

Next, a first example of a locking device 30 according to the present embodiment will be described with reference to FIGS. 2 to 4.

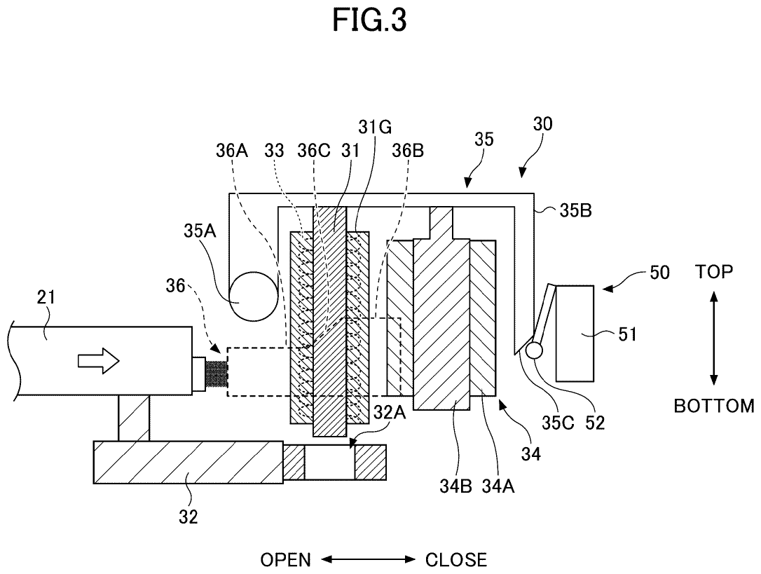

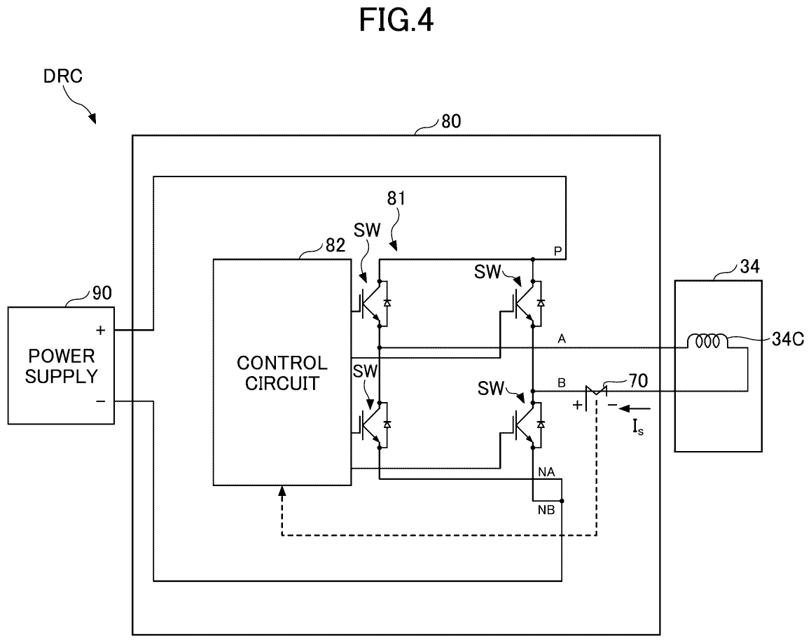

FIGS. 2 and 3 are drawings illustrating the first example of a locking device 30 of the door 10. FIG. 4 is a drawing illustrating the first example of a driving circuit DRC for the locking device 30.

Specifically, FIG. 2 drawing is a illustrating the first example of the locking device 30 when the door 10 is in the fully closed position and the door 10 is locked by the locking device 30. FIG. 3 is a drawing illustrating the first example of the locking device 30 when the door 10 is in the fully closed state and the door 10 is locked by the locking device 30. FIG. 4 is a drawing illustrating a specific example of the driving circuit DRC for electrically driving the locking device 30 shown in FIGS. 2 and 3.

In FIGS. 2 and 3, an illustration of the door 10 disposed below the locking device 30 is omitted. In FIGS. 2 and 3, the left direction represents the opening direction of the door 10, and the right direction represents the closing direction of the door 10.

As shown in FIGS. 2 and 3, in this example, the locking device 30 includes a lock pin 31, an opening and closing interlocking member 32, a biasing spring 33, the solenoid 34, a vertical slider 35, and a horizontal slider 36.

The lock pin 31 is supported by a guide 31G so as to be movable in a predetermined range (hereinafter, “range of motion”) in the vertical direction. The guide 31G is attached to the vehicle body of the railway vehicle 1 as a fixed part directly or via another member such as a bracket.

The opening and closing interlocking member 32 is directly or indirectly connected to the door 10, and moves in the opening and closing directions in conjunction with the opening and closing motions of the door 10, respectively. As shown in FIGS. 2 and 3, in this example, the opening and closing interlocking member 32 is connected to the moving element 21 of the linear motor included in the door driving mechanism 20, and interlocks with the movement of the moving element 21 in the opening and closing directions. The opening and closing interlocking member 32 is disposed below the lock pin 31 in the vertical direction, and has a lock hole 32A.

The lock hole 32A is a recess provided on the upper surface of the opening and closing interlocking member 32, and is disposed so that the lock pin 31 can be inserted from above in the fully closed position of the door 10. In addition, the lock pin 31 is disposed so that its lower end is above and below the opening of the lock hole 32A in the upper and lower stroke ends (i.e., the upper and lower limit positions) of the vertical range of motion of the lock pin 31. Thus, when the door 10 is in the fully closed position, the lock pin 31 is inserted into the lock hole 32A from above to regulate the opening and closing operation of the door 10 and lock the door 10. For example, as shown in FIGS. 2 and 3, the lock hole 32A may penetrate the opening and closing interlocking member 32 vertically, or may only be opened upward and not penetrate downward. The lock hole 32A may be a recess for regulating the opening and closing operation of the door 10 as shown in FIGS. 2 and 3, or may be a structure for regulating the movement of the door 10 only in the opening direction.

The biasing spring 33 is arranged so as to bias the lock pin 31 downward when the lock pin 31 is at least at the upper limit position of the range of motion in the vertical direction. Thus, the biasing spring 33 can bias the lock pin 31 to be inserted into the lock hole 32A when the door 10 is in the fully closed position.

Specifically, in the locking device 30, the opening and closing interlocking member 32 moves to a position corresponding to the fully closed state of the door 10 in accordance with the closing operation of the door 10, thereby shifting the state in which the lock hole 32A does not exist directly below the lock pin to a state in which it exists directly below the lock pin 31. The state in which the lock hole 32A is not located directly below the lock pin 31 is a state in which part or all of the lower end of the lock pin 31 is not included in the range of the lock hole 32A in the top view of the locking device 30, and corresponds to a state in which the lock pin 31 cannot be inserted into the lock hole 32A. Conversely, the state in which the lock hole 32A is located directly below the lock pin 31 is a state in which all of the lower end of the lock pin 31 is included in the range of the lock hole 32A in the top view of the locking device 30, and corresponds to a state in which the lock pin 31 can be inserted into the lock hole 32A. Then, the locking device 30 can lock the door 10 by the biasing force of the biasing spring 33 by shifting to a state in which the lock hole 32A is located directly below the lock pin 31.

In addition to the biasing spring 33, the self-weight of the lock pin 31 acts as a biasing force on the lock pin 31. Therefore, the biasing spring 33 may be omitted and the locked state of the door 10 may be achieved only by the self-weight of the lock pin 31.

The solenoid 34 is an actuator that moves the lock pin 31 upward through the vertical slider 35. The solenoid 34 includes a housing 34A, a plunger 34B and a coil 34C housed in the housing 34A.

When no current flows through the coil 34C, the upper end of the plunger 34B has zero or relatively small protrusion from the housing 34A (hereinafter, simply referred to as “the protrusion of the plunger 34B”). Conversely, when a current flows through the coil 34C, the plunger 34B is attracted by a fixed core magnetized by the coil 34C, thereby moving upward, and its upper end greatly protrudes upward from the housing 34A.

For example, as shown in FIG. 4, the driving circuit DRC of the locking device 30 includes a power supply 90, a coil 34C, and an inverter circuit 81.

One end of the coil 34C is connected to an A-phase output of the inverter circuit 81, and the other end is connected to a B-phase output of the inverter circuit 81.

For example, the inverter circuit 81 is incorporated in the door control device 80. Controlled by a control circuit 82 of the door control device 80, it can apply a voltage to the coil 34C in a predetermined pattern by using the power supplied from the power supply 90, and thus energize the coil 34C. The inverter circuit 81 may also be disposed outside the door control device 80. For example, the control circuit 82 can control the current of the coil 34C by appropriately turning ON or OFF a switching element SW of the inverter circuit 81 by a PWM (Pulse Width Modulation) signal in response to a current command Ic.

The current sensor 70 detects the current Is of the coil 34C, and the detection signal is received into the control circuit 82. Thus, the control circuit 82 can feedback control the current Is of the coil 34C based on the detection signal of the current sensor 70.

The vertical slider 35 is directly or indirectly attached to the vehicle body of the railway vehicle 1, and can be moved in the vertical direction with reference to the vehicle body as a fixed part. The vertical slider 35 is arranged so as to cover the upper parts of the lock pin 31 and the solenoid 34, and is directly or indirectly connected to the lock pin 31 through another member, and the plunger 34B can be abutted. As a result, the plunger 34B of the solenoid 34 largely protrudes upward from the housing 34A, so that the vertical slider 35 is moved upward, and as a result, the lock pin 31 can be moved upward. Therefore, the solenoid 34 releases the state in which the lower end of the lock pin 31 is inserted into the lock hole 32A in the fully closed position of the door 10, and can shift the door 10 from the locked state to the unlocked state.

The horizontal slider 36 can move in the opening and closing direction of the door 10 in conjunction with the opening and closing operation of the door 10. In this example, the horizontal slider 36 can move in the opening and closing direction of the door 10 in conjunction with the operation of the moving element 21. The horizontal slider 36 can abut against an abutting part 35A of the vertical slider 35 and support the vertical slider 35 from below. The horizontal slider 36 includes support surfaces 36A to 36C.

The support surface 36A is located below the abutting part 35A of the vertical slider 35 in a state where the horizontal slider 36 is at a position corresponding to the fully closed state of the door 10. The support surface 36A is arranged so that it can abut against the abutting part 35A of the vertical slider 35 in a state where the lock pin 31 is inserted into the lock hole 32A.

The support surface 36B is located below the abutting part 35A of the vertical slider 35 in a state where the horizontal slider 36 is moved to some extent in the opening direction of the door 10 with reference to the position corresponding to the fully closed state of the door 10. The support surface 36B is located above the support surface 36A in the vertical direction and is arranged so that it can abut against the abutting part 35A of the vertical slider 35 in a state where the plunger 34B of the solenoid 34 is at the upper stroke end (i.e., the upper limit position).

The support surface 36C is formed as a slope connecting the support surface 36A and the support surface 36B in the opening and closing direction of the door 10.

At the start of the opening operation of the door 10, the door 10 is shifted from the locked state to the unlocked state by the locking device 30, and as a result, the plunger 34B largely protrudes from the housing 34A. Therefore, in a state where the abutting part 35A of the vertical slider 35 is above the support surface 36A of the horizontal slider 36, more specifically, at the same height as the support surface 36B, the horizontal slider 36 starts moving in the opening direction of the door 10 in conjunction with the opening operation of the door 10. When the door 10 moves to some extent from the fully closed state to the opening direction, the support surface 36B of the horizontal slider 36 is positioned below the abutting part 35A of the vertical slider 35. Therefore, even when the coil 34C of the solenoid 34 is finished energizing and the upper end of the plunger 34B is released from the protruding state from the housing 34A, the vertical position of the vertical slider 35 is maintained by supporting the abutting part 35A of the vertical slider 35 by the support surface 36B.

Conversely, in the closing operation of the door 10, the position of the horizontal slider 36 where the abutting part 35A of the vertical slider 35 can abut changes in an order of the support surface 36B, the support surface 36C, and the support surface 36A as the door 10 moves from the fully open position to the fully closed position. Therefore, when the lock hole 32A reaches directly below the lock pin 31 with the closing operation of the door 10, the lock pin 31 is automatically inserted into the lock hole 32A by the biasing force of the biasing spring 33 and the self-weight of the lock pin 31. As a result, the locking device 30 can lock the door 10 in accordance with the closing operation of the door 10.

For example, the locking detection switch 50 is arranged so as to be adjacent to the lateral surface 35B of the vertical slider 35. The locking detection switch 50 includes a body part 51 and an actuator part 52.

The locking detection switch 50 is a momentary switch, and a biasing force is applied to the actuator part 52 so as to maintain the state in which the actuator part 52 is separated from the body part 51, that is, the OFF state.

As shown in FIG. 2, when the lock pin 31 is inserted into the lock hole 32A and the door 10 is locked, a tip of the actuator part 52 abuts against the lateral surface 35B of the vertical slider 35 and is pressed toward the body part 51. As a result, the locking detection switch 50 is turned ON in accordance with the locked state of the door 10.

Conversely, as shown in FIG. 3, when the lock pin 31 is not inserted into the lock hole 32A and the door 10 is locked, the tip of the actuator part 52 and the lateral surface 35B of the vertical slider 35 are not adjacent to each other in the opening and closing direction of the door 10. Therefore, the state in which the tip of the actuator part 52 abuts against the lateral surface 35B of the vertical slider 35 is released, and as a result, the locking detection switch 50 is turned off in accordance with the locked state of the door 10.

The lower end surface 35C adjacent to the lower end of the lateral surface 35B of the vertical slider 35 is inclined downward in a direction away from the locking detection switch 50. Therefore, when the door 10 is locked by the locking device 30, the tip of the actuator part 52 of the locking detection switch 50 is released from the state of abutting against the lateral surface 35B, and then continues to abut on the lower end surface 35C of the vertical slider 35. As a result, as the vertical slider 35 rises, the tip of the actuator part 52 abuts against the lower end surface 35C of the vertical slider 35, switching the locking detection switch 50 from ON to OFF. When the door 10 is locked by the locking device 30, the tip of the actuator part 52 of the locking detection switch 50 abuts on the lower end surface 35C of the vertical slider 35 according to the fall of the vertical slider 35 after inserting the lock pin 31 into the lock hole 32A. Then, the tip of the actuator part 52 of the locking detection switch 50 approaches the lateral surface 35B while abutting against the lower end surface 35C of the vertical slider 35 according to the fall of the vertical slider 35, and shifts to the state of abutting against the lateral surface 35B. As a result, the locking detection switch 50 switches from OFF to ON while abutting against the lower end surface 35C of the vertical slider 35 according to the fall of the vertical slider 35.

### First Example of Locking Device State Monitoring Method

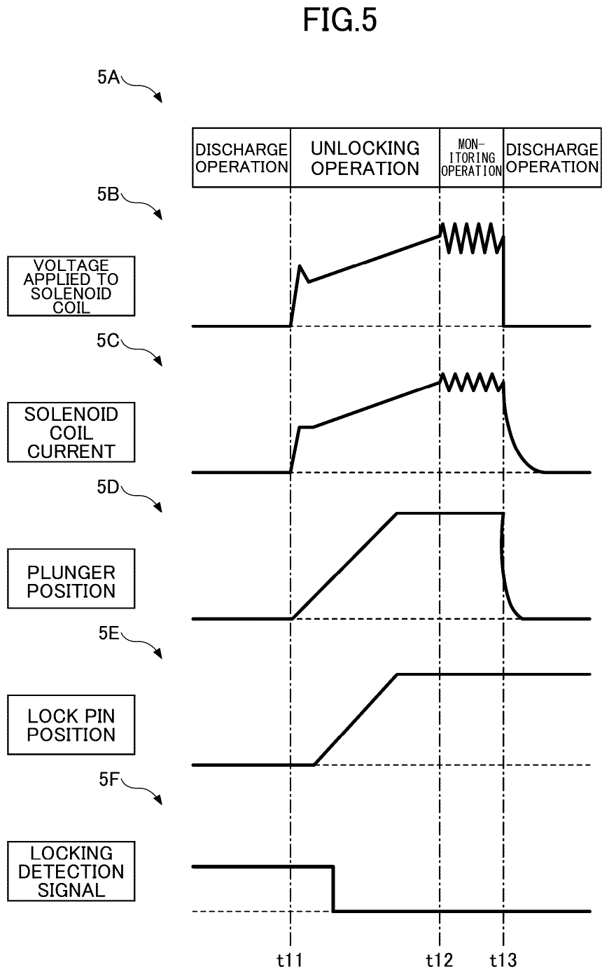

Next, with reference to FIGS. 5 to 7, a first example of monitoring the state of the locking device 30 by the door control device 80 will be described.

Hereinafter, this example will be described assuming the configuration of the locking device 30 shown in FIGS. 2 and 3 and the driving circuit DRC shown in FIG. 4.

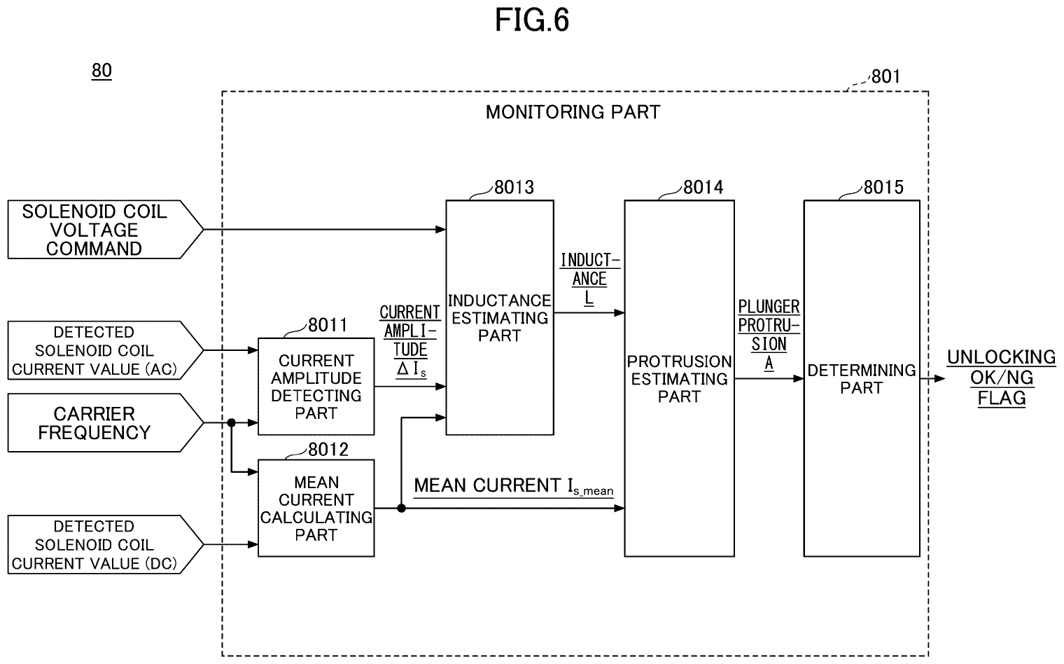

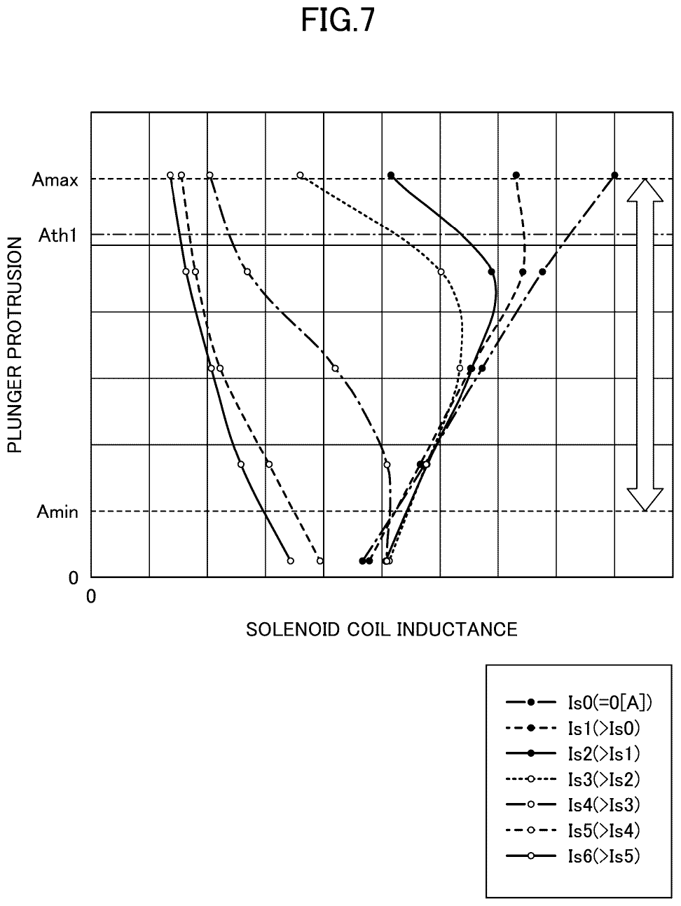

FIG. 5 is a time chart illustrating a first example of a method for monitoring the state of the locking device 30. FIG. 6 is a functional block diagram illustrating the first example of the configuration related to a function for monitoring the state of the locking device 30. FIG. 7 is a drawing illustrating an example of a correlation between protrusion A of the plunger 34B and the solenoid coil (coil 34C) inductance L, and the first example of a monitoring reference for the protrusion of the plunger 34B.

Specifically, FIG. 5 includes Portions 5A to 5F. Portion 5A is a time chart illustrating an operation flow of the driving circuit DRC when the locking device 30 unlocks the door 10. Portions 5B to 5F are time charts illustrating an example of an unlocking operation of the locking device 30 when the locking device 30 is in a normal state. Portion 5B is a time chart illustrating a time variation of the applied voltage of the solenoid coil (coil 34C) when the locking device 30 unlocks the door 10. Portion 5C is a time chart illustrating a time variation of the current of the solenoid coil (coil 34C) when the locking device 30 unlocks the door 10. Portion 5D is a time chart illustrating a time variation in the vertical position of the plunger 34B when the locking device 30 unlocks the door 10. Portion 5E is a time chart illustrating a time variation in the vertical position of the lock pin 31 when the locking device 30 unlocks the door 10. Portion 5F is a time chart illustrating a time variation in the detection signal (hereinafter, “locking detection signal”) of the locking detection switch 50 when the locking device 30 unlocks the door 10.

FIG. 7 shows a correlation between the protrusion A of the plunger 34B and the inductance L of the solenoid coil (coil 34C) when the mean value of the current Is of the coil 34C (mean current I_{s_mean}) is in the range of seven predetermined values Is0 (=0 [A]) to Is6.

As shown in Portion 5A, at a time t11, the driving circuit DRC shifts from a discharge operation state to the operation for unlocking the door 10 (unlocking operation) controlled by the control circuit 82. In the discharge operation of the driving circuit DRC, both switching elements SW of the lower arm of the inverter circuit 81 are turned ON to discharge energy stored in the coil 34C.

As shown in Portions 5B and 5C, in the unlocking operation of the driving circuit DRC, a direct voltage of a predetermined pattern is applied to the coil 34C controlled by the control circuit 82, and a direct current of a predetermined pattern is applied by the feedback control. Accordingly, as shown in Portion 5D, the plunger 34B starts moving upward at the time t11, and then, as shown in Portion 5E, the plunger 34B comes into contact with the vertical slider 35, and the lock pin 31 starts moving upward. Subsequently, as shown in Portion 5F, as the plunger 34B moves upward, the locking detection signal is switched from ON to OFF.

As shown in Portion 5D, the plunger 34B continues moving upward by energizing the coil 34C, and reaches the upper stroke end (i.e., the upper limit position). As a result, as shown in Portion 5E, as the plunger 34B moves upward, the lock pin 31 reaches the upper limit position, and the locking device 30 can achieve the fully unlocked state of the door 10.

After the plunger 34B reaches the upper limit position, at a time t12, the driving circuit DRC shifts from the unlocking operation to the operation for monitoring the state of the locking device 30 (hereinafter, “monitoring operation”) controlled by the control circuit 82.

As shown in Portions 5B and 5C, in the monitoring operation of the driving circuit DRC, controlled by the control circuit 82, an alternating voltage of amplitude and a a predetermined predetermined frequency based on a predetermined voltage is applied to the coil 34C, and an alternating current flows through the coil 34C. At this time, the predetermined voltage is, for example, the voltage applied to the coil 34C at the end of the locking operation, as shown in Portion 5B.

As shown in Portion 5A, when the monitoring operation is completed, the driving circuit DRC shifts to the discharge operation at a time t13.

For example, the door control device 80 executes the unlocking operation and the monitoring operation according to this example in accordance with the opening operation of the door 10 during an actual operation of the railway vehicle 1. Thus, for example, the door control device 80 can monitor the state of the locking device 30 in real time during the actual operation of the railway vehicle 1. Further, the door control device 80 may execute the unlocking operation and the monitoring operation according to this example in accordance with the opening operation of the door 10 during an inspection of the railway vehicle 1 at a rail yard or the like.

The door control device 80 monitors the state of the locking device 30 based on the voltage value and the current value of the coil 34C during the monitoring operation of the driving circuit DRC.

For example, as shown in FIG. 6, the door control device 80 includes a monitoring part 801 as a function part for monitoring the state of the locking device 30.

The monitoring part 801 includes a current amplitude detecting part 8011, a mean current calculating part 8012, an inductance estimating part 8013, a protrusion estimating part 8014, and a determining part 8015. These functions may be achieved by a hardware arithmetic circuit or the like, or may be achieved by loading the program installed in the auxiliary storage device of the computer into the memory device and executing it by the CPU.

The current amplitude detecting part 8011 detects the amplitude of the current Iₛ (current amplitude ΔIₛ) of the coil 34C during the monitoring operation of the driving circuit DRC based on the output of the current sensor 70 and a carrier frequency of the PWM signal of the inverter circuit 81.

The mean current calculating part 8012 calculates the mean value (mean current I_{s_mean}) of the current Iₛ of the coil 34C during the monitoring operation of the driving circuit DRC based on the output of the current sensor 70 and the carrier frequency of the PWM signal of the inverter circuit 81.

The inductance estimating part 8013 estimates the inductance L of the solenoid coil (coil 34C) based on the current amplitude ΔIₛ, the mean current I_{s_mean}, and the applied voltage Vₛ of the coil 34C during the monitoring operation of the driving circuit DRC. The applied voltage Vₛ of the coil 34C may be a voltage command value or a measured value.

In the monitoring operation of the driving circuit DRC, the following equation 1 is established among the current amplitude ΔIₛ of the coil 34C, the applied voltage V_{L} to the inductance portion of the coil 34C, and an application time t of the voltage to the coil 34C by the PWM signal.

$$\begin{matrix}[ Equation 1 ] & \\ Δ {I}_{s} = \frac{{V}_{L}}{L} \cdot t & ( 1 )\end{matrix}$$

In the monitoring operation of the driving circuit DRC, the following equation 2 is established among the applied voltage V_{L} to the inductance portion of the coil 34C, the applied voltage Vₛ to the coil 34C, the mean current I_{s_mean} of the coil 34C, and resistance Rₛ of the coil 34C.

$$\begin{matrix}[ Equation 2 ] & \\ {V}_{L} = {V}_{s} - {I}_{s \_ mean} \cdot {R}_{s} & ( 2 )\end{matrix}$$

Therefore, the inductance L of the coil 34C is expressed by the following equation 3 from 1 and 2.

$$\begin{matrix}[ Equation 3 ] & \\ L = \frac{{V}_{L}}{Δ {I}_{s}} \cdot t & ( 3 )\end{matrix}$$

Therefore, the inductance estimating part 8013 can estimate the inductance L of the coil 34C during the monitoring operation of the driving circuit DRC using equation 3.

The protrusion estimating part 8014 estimates the protrusion A of the plunger 34B from the housing 34A during the monitoring operation of the driving circuit DRC based on the estimated value of the inductance L of the coil 34C estimated by the inductance estimating part 8013. When the vertical position of the plunger 34B changes, the length of the magnetic path in the solenoid 34 changes. Therefore, the protrusion estimating part 8014 estimates the vertical position of the plunger 34B from the estimated value of the inductance L using this characteristic.

The protrusion estimating part 8014 estimates the protrusion A of the plunger 34B from the estimated value of the inductance L of the coil 34C using, for example, information (hereinafter, referred to as “correlation information” for convenience) representing the correlation between the inductance L of the coil 34C and the protrusion A of the plunger 34B. The correlation information is, for example, a conversion equation or a lookup table.

For example, as shown in FIG. 7, the correlation between the inductance L of the coil 34C and the protrusion A of the plunger 34B differs depending on the magnitude of the mean current I_{s_mean} of the coil 34c. Therefore, the correlation information corresponding to the magnitude of the mean current I_{s_mean} during the monitoring operation of the driving circuit DRC is prepared in advance. In addition, in consideration of the variation of the inductance L of the coil 34C, the estimated value of the inductance L of the coil 34C may be corrected by gain compensation or offset compensation before applying the correlation information. For example, the protrusion estimating part 8014 corrects the estimated value of the inductance L by gain compensation or offset compensation according to the variation of the inductance L among the parts of the solenoid 34. In addition, in consideration of the variation of the inductance L of the coil 34C, a plurality of correlation information corresponding to the same mean current I_{s_mean} may be prepared. For example, a plurality of correlation information corresponding to the variation of the operating temperature environment of the locking device 30 may be prepared in advance, and the protrusion estimating part 8014 selects the appropriate correlation information according to the operating temperature environment of the locking device 30 (e.g., air temperature near the locking device 30).

The determining part 8015 determines the unlocking state of the door 10 by the locking device 30 based on the estimated value of the protrusion A of the plunger 34B during the monitoring operation of the driving circuit DRC estimated by the protrusion estimating part 8014.

For example, the determining part 8015 determines whether the protrusion A of the plunger 34B is equal to or greater than the threshold Ath1. As shown in FIG. 7, the threshold Ath1 is a positive value (Ath1>0) and is preset as a value between the maximum value Amax and the minimum value Amin of the protrusion A of the plunger 34B (specifically, 0≤Amin<Ath1<Amax).

For example, the threshold Ath1 is set as a lower limit value of the plunger 34B protrusion A to achieve a state in which the lock pin 31 is not inserted into the lock hole 32A. Specifically, the threshold Ath1 is set as the sum (i.e., the added value) of the initial value of the plunger 34B protrusion, a gap between the plunger 34B and the vertical slider 35, and a vertical lap amount between the lock pin 31 and the lock hole 32A in the locked state of the door 10. The initial value of the plunger 34B protrusion means the initial state in which the coil 34C is not energized in the normal state of the solenoid 34, that is, the upward protrusion of the plunger 34B from the housing 34A at the lower stroke end of the plunger 34B (i.e., the lower limit position). The initial value of the plunger 34B protrusion corresponds to the minimum value Amin described above. The gap between the plunger 34B and the vertical slider 35 means the vertical gap between the vertical slider 35 at the lower stroke end (i.e., the lower limit position) and the plunger 34B at the lower limit position. The vertical lap amount between the lock pin 31 and the lock hole 32A in the locked state of the door 10 means the vertical insertion depth of the lock pin 31 to the lock hole 32A when the lock pin 31 is at the lower limit position. Thus, when the estimated value of the plunger 34B protrusion A is equal to or greater than the threshold Ath1, the determining part 8015 can determine that the lower end of the lock pin 31 is at the same or higher vertical position than the opening of the lock hole 32A, and that the door 10 is normally unlocked. Conversely, when the estimated value of the plunger 34B protrusion A is less than the threshold Ath1, the determining part 8015 can determine that the door 10 is not normally unlocked by the locking device 30.

The determining part 8015 outputs to the outside a flag representing the determination result, that is, a locking OK flag representing that the door 10 is normally unlocked, or a locking NG flag representing that the door 10 is not normally unlocked.

For example, the determining part 8015 transmits a flag indicating the determination result to the host device of the railway vehicle 1. Thus, the host device can output the determination result from a display device or a sound output device in the operator's cabin or the conductor's cabin of the railway vehicle 1. Thus, it is possible to notify the operator, conductor, or other crew member of the railway vehicle 1 whether or not the door 10 is normally unlocked.

In addition to the determination result of the determining part 8015, the determining part 8015 may also transmit to the host device various information (hereinafter, “incidental information”) obtained by the monitoring part 801 during the monitoring operation of the driving circuit DRC. The accompanying information includes not only information calculated or estimated by each function of the monitoring part 801, but also source information for acquiring the information. Thus, the host device can store the log composed of the combination of the determination result and the accompanying information in the storage device mounted on the railway vehicle 1, or can transmit the log to an external device and store the log in the external device. Therefore, for example, an inspector can check the accumulated log after the fact to confirm the state of the unlocking operation of the door 10 by the locking device 30 during operation of the railway vehicle 1. In addition, the door control device 80, the host device, or the external device may analyze the accumulated log to predict the deterioration state and the life of the lock pin 31, solenoid 34, and the like of the locking device 30.

As described above, in this example, after the unlocking operation of the driving circuit DRC is completed, the door control device 80 causes the driving circuit DRC to execute a monitoring operation for applying an alternating voltage to the coil 34C. The door control device 80 can monitor whether the door 10 is normally unlocked by estimating the inductance of the coil 34C based on the voltage and current of the coil 34C during the monitoring operation of the driving circuit DRC.

### First Example of Control Processing of Door Control Device

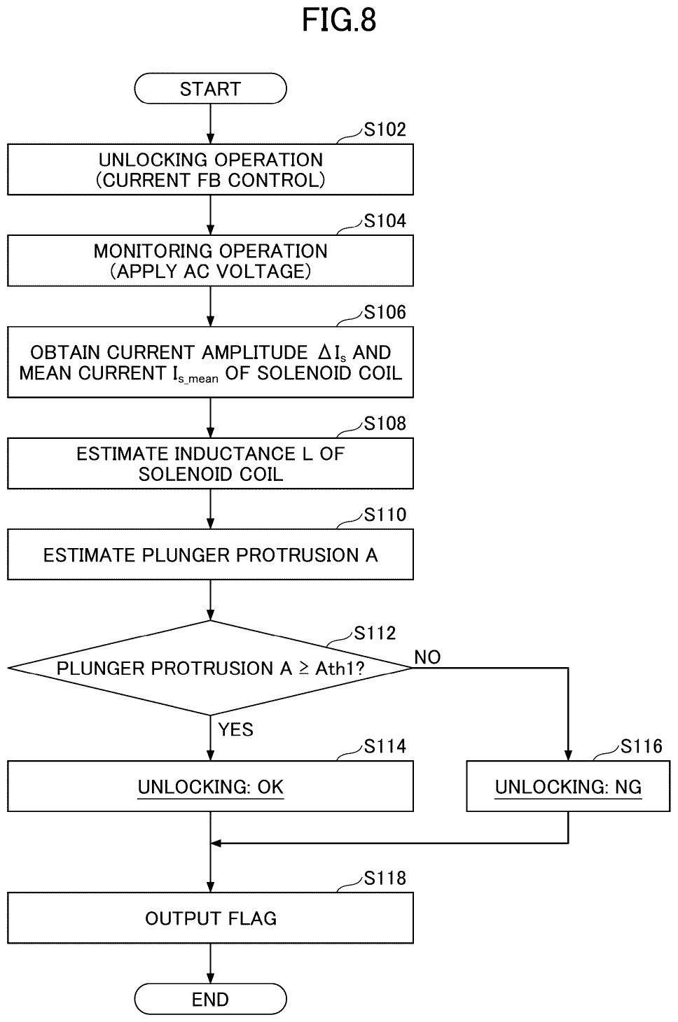

Next, a first example of control processing of the door control device 80 will be described with reference to FIG. 8. Specifically, a specific example of control processing of the door control device 80 including a processing flow corresponding to the first example of the monitoring method of the state of the locking device 30 will be described.

FIG. 8 is a flowchart schematically illustrating the first example of control processing of the door control device 80.

This flowchart starts when, for example, a command from the host device instructing the door 10 to open is input to the door control device 80.

As shown in FIG. 8, in a step S102, the circuit 82 of the door control device 80 control controls the inverter circuit 81 and causes the driving circuit DRC to execute the unlocking operation. At this time, the control circuit 82 performs current feedback control of the coil 34C according to a predetermined current pattern based on the output of the current sensor 70 as described above.

When the process of the step S102 is completed, the door control device 80 proceeds to a step S104.

In the step S104, the control circuit 82 of the door control device 80 controls the inverter circuit 81 and causes the driving circuit DRC to execute the monitoring operation. At this time, the control circuit 82 applies an alternating voltage to the coil 34C by the driving circuit DRC as described above.

When the processing of the step S104 is completed, the door control device 80 proceeds to a step S106.

In the step S106, the monitoring part 801 of the door control device 80 obtains the current amplitude ΔIₛ and the mean current I_{s_mean} of the solenoid coil (coil 34C) during the monitoring operation by the functions of the current amplitude detecting part 8011 and the mean current calculating part 8012.

When the processing of the step S106 is completed, the door control device 80 proceeds to a step S108.

In the step S108, the monitoring part 801 of the door control device 80 estimates the inductance L of the coil 34C of the solenoid 34 during the monitoring operation of the driving circuit DRC by the function of the inductance estimating part 8013.

When the processing of the step S108 is completed, the door control device 80 proceeds to a step S110.

In the step S110, the monitoring part 801 of the door control device 80 estimates the protrusion A of the plunger 34B during the monitoring operation of the driving circuit DRC by the function of the protrusion estimating part 8014.

When the processing of the step S110 is completed, the door control device 80 proceeds to a step S112.

In the step S112, the monitoring part 801 of the door control device 80 determines whether or not the estimated value of the protrusion A of the plunger 34B during the monitoring operation of the driving circuit DRC is equal to or greater than the threshold Ath1 by the function of the determining part 8015. When the estimated value of the protrusion A of the plunger 34B is equal to or greater than the threshold Ath1, the monitoring part proceeds to a step S114, and when it is not equal to or greater than the threshold Ath1, the monitoring part 801 proceeds to a step S116.

In the step S114, the monitoring part 801 of the door control device 80 determines that the door 10 is normally unlocked (i.e., “Unlock: OK”) by the locking device 30 by the function of the determining part 8015.

Conversely, in the step S116, the monitoring part 801 of the door control device 80 determines that the door 10 is not normally unlocked (i.e., “Unlock: NG”) by the locking device 30 by the function of the determining part 8015.

When the processing of the step S114 or the step S116 is completed, the door control device 80 proceeds to a step S118.

In the step S118, the monitoring part 801 of the door control device 80 outputs to the outside a flag indicating a determination result as to whether or not the door 10 is normally unlocked by the locking device 30 by the function of the determining part 8015.

When the processing of the step S118 is completed, the door control device 80 completes the processing of the present flowchart.

### Second Example of Locking Device State Monitoring Method

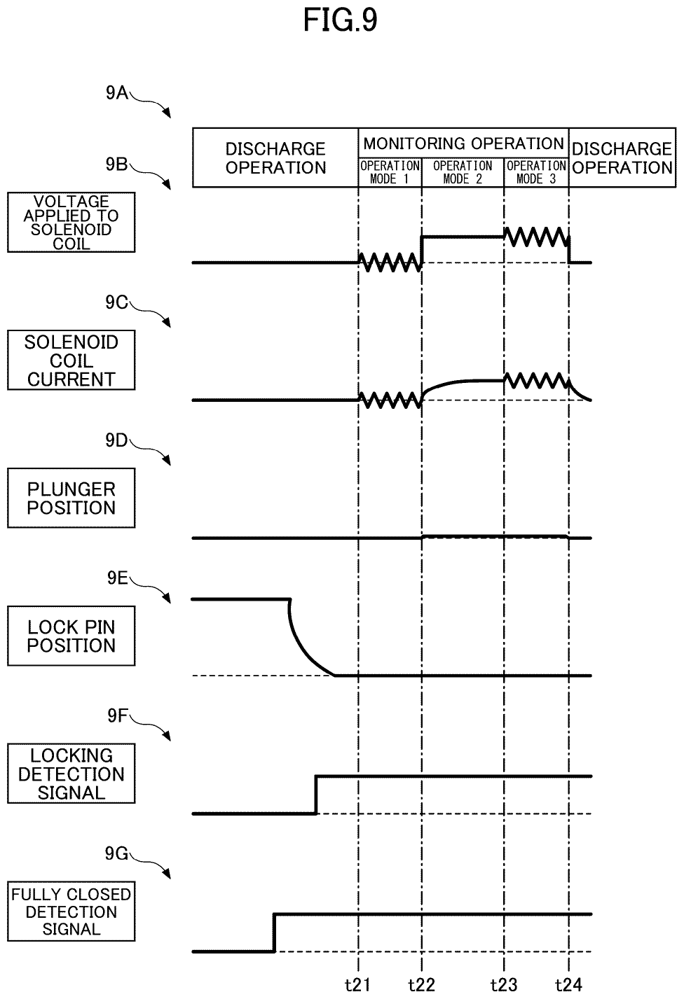

Next, with reference to FIGS. 9 to 17, a second example of monitoring the state of the locking device 30 by the door control device 80 will be described.

Hereinafter, in this example, the configuration of the locking device 30 shown in FIGS. 2 and 3 and the driving circuit DRC shown in FIG. 4 will be assumed as in the first example of the monitoring method described above. Also, in this example, the same reference numerals will be given to the same or corresponding configurations as in the first example of the monitoring method described above, and the description will be given mainly on the parts different from the first example of the monitoring method described above, and the same or corresponding components as in the first example of the monitoring method described above may be omitted.

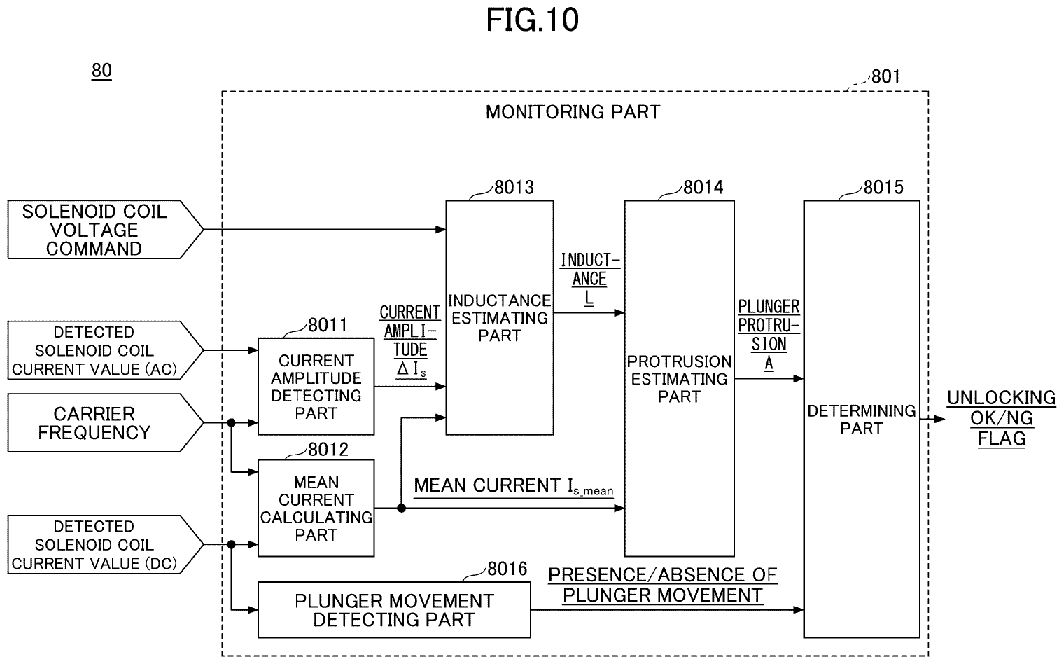

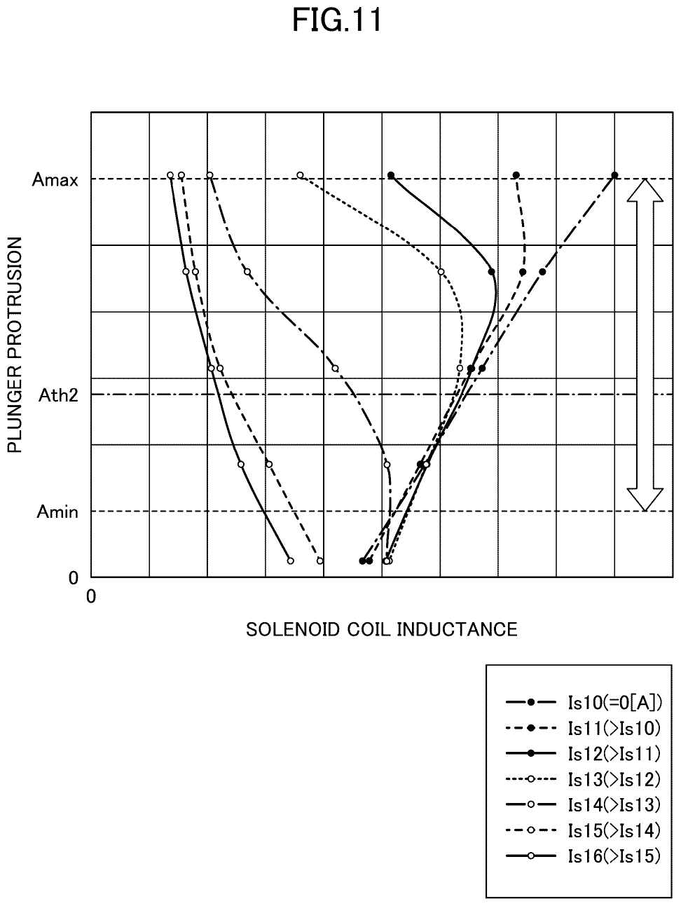

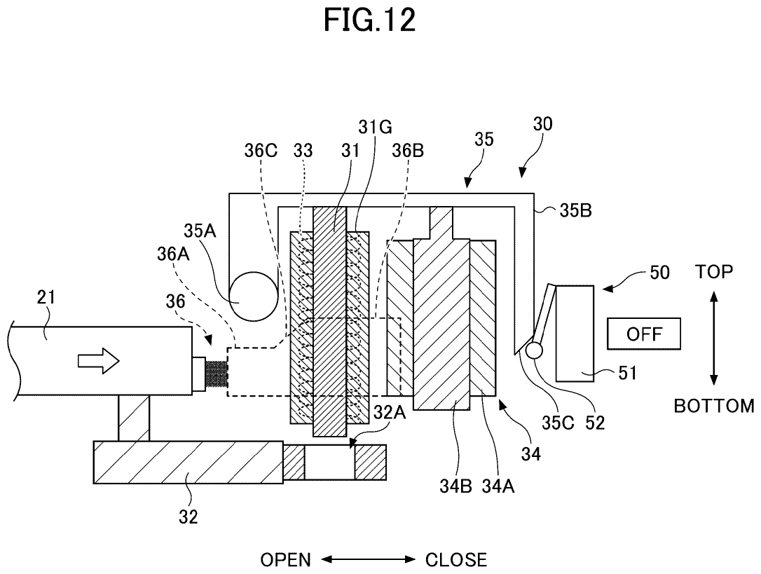

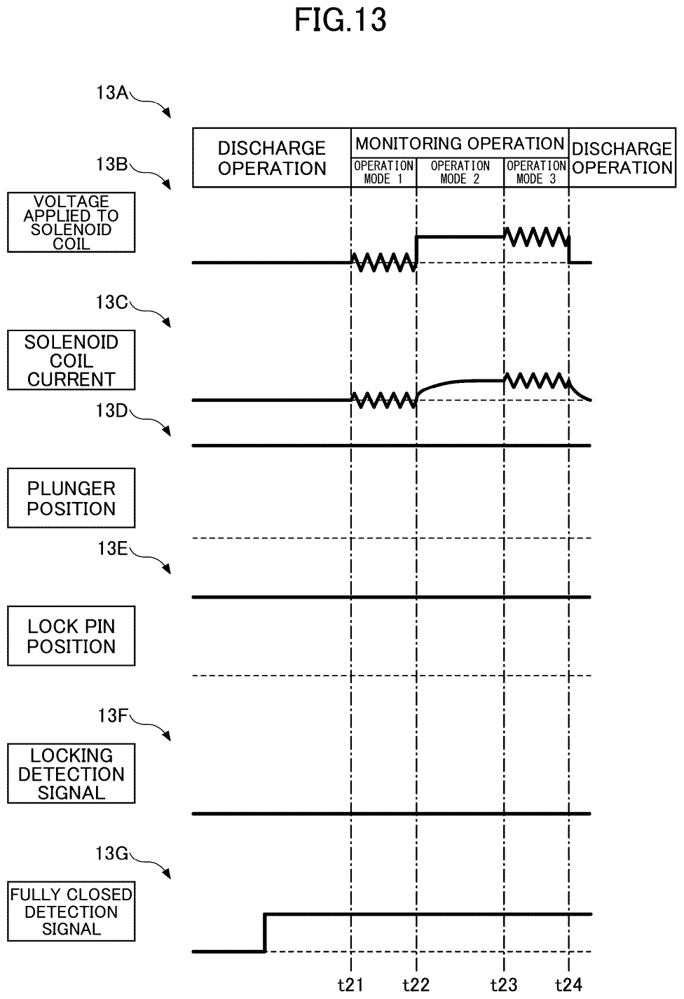

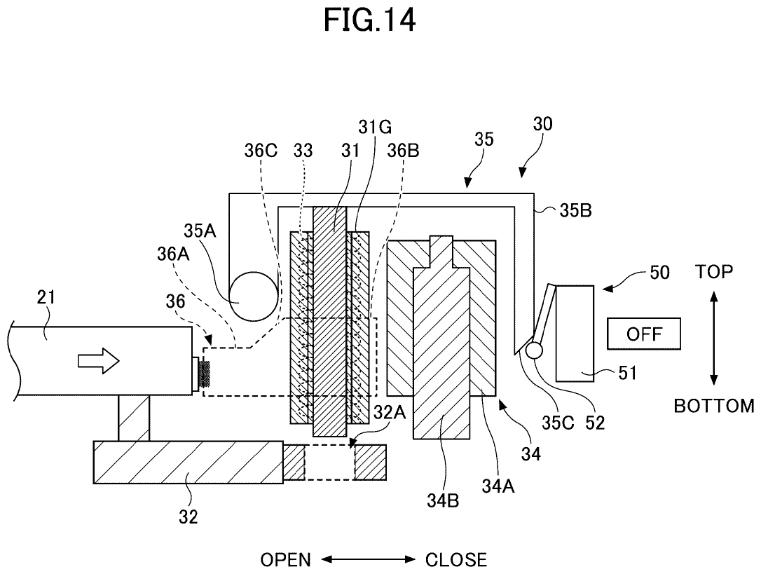

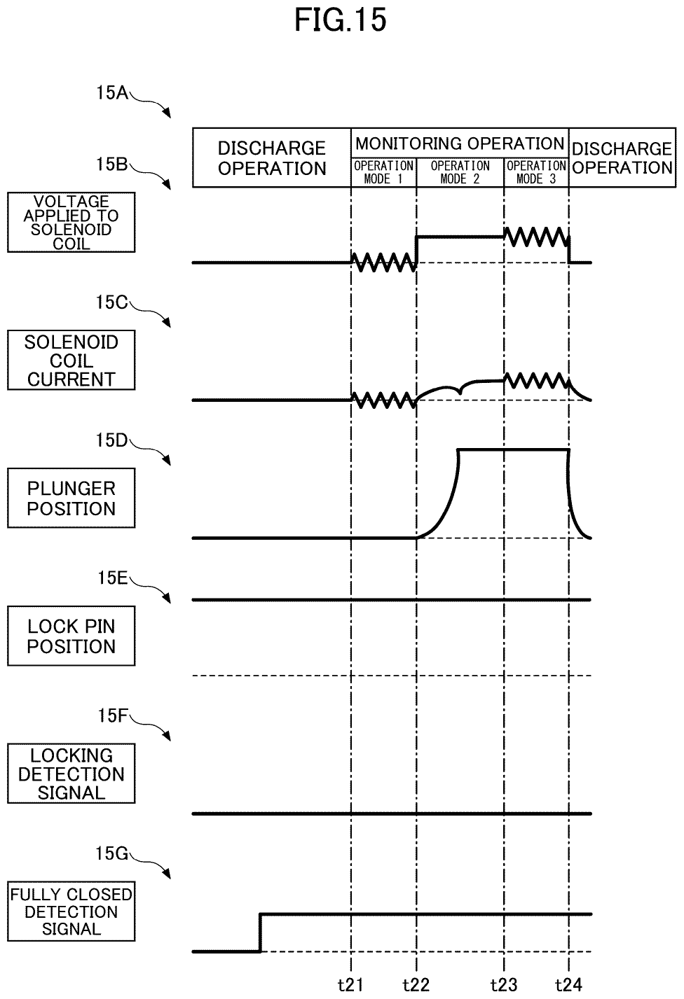

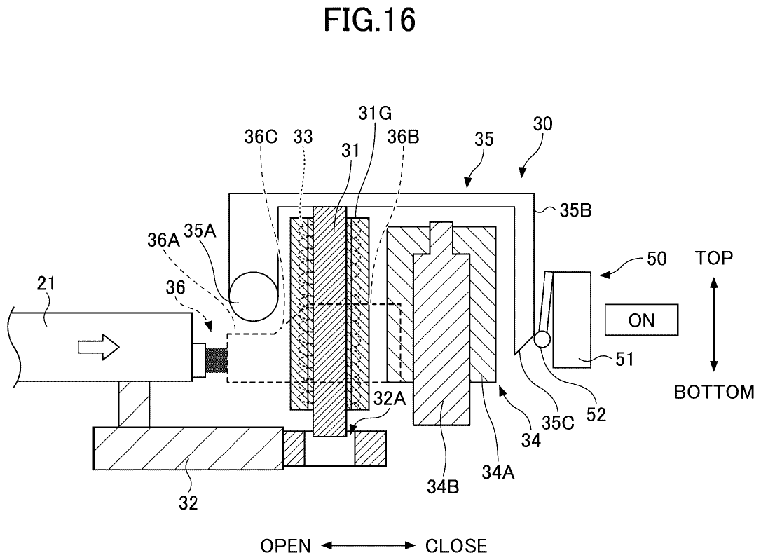

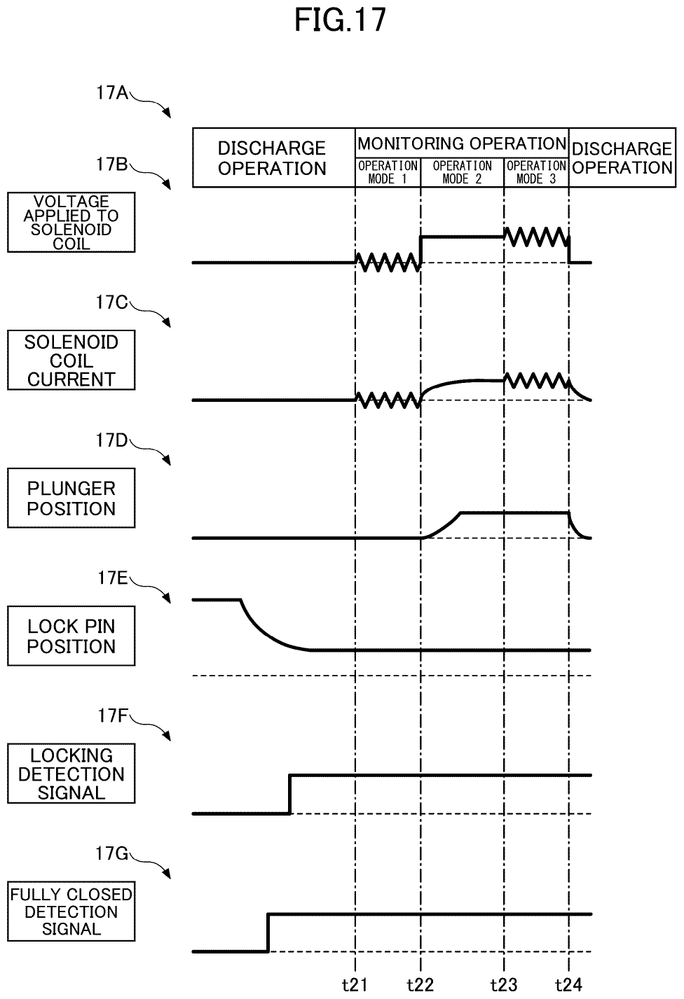

FIG. 9 is a time chart describing the second example of the method for monitoring the state of the locking device 30. FIG. 10 is a functional block diagram illustrating the second example of a configuration related to a function for monitoring the state of the locking device 30. FIG. 11 is a drawing illustrating an example of the inductance of correlation between the protrusion A of the plunger 34B and the solenoid coil (coil 34C), and the second example of the monitoring reference for the protrusion A of the plunger 34B. FIG. 12 is a drawing illustrating an example of the state at the time of completion of the locking operation of the locking device 30 when the locking device 30 is abnormal. FIG. 13 is a time chart describing an example of the locking operation of the locking device 30 when the locking device 30 is abnormal. FIG. 14 is a drawing illustrating another example of the state at the time of completion of the locking operation of the locking device 30 when the locking device 30 is abnormal. FIG. 15 is a time chart explaining another example of the locking operation of the locking device 30 when the locking device 30 is abnormal. FIG. 16 is a drawing illustrating yet another example of the state at the time of completion of the locking operation of the locking device 30 when the locking device 30 is abnormal. FIG. 17 is a time chart explaining yet another example of the locking operation of the locking device 30 when the locking device 30 is abnormal.

Specifically, FIG. 9 includes portions 9A to 9F. Portion 9A is a time chart illustrating the flow of the operation of the driving circuit DRC when the locking device 30 locks the door 10. Portions 9B-9G are time charts illustrating an example of a normal locking operation of the locking device 30. Portion 9B is a time chart illustrating the time variation of the applied voltage of the solenoid 34 (specifically, coil 34C) when the locking device 30 locks the door 10. Portion 9C is a time chart illustrating the time variation of the current of the solenoid 34 (specifically, coil 34C) when the locking device 30 locks the door 10. Portion 9D is a time chart illustrating the time variation of the vertical position of the plunger 34B when the locking device 30 locks the door 10. Portion 9E is a time chart illustrating the time variation of the vertical position of the lock pin 31 when the locking device 30 locks the door 10. Portion 9F is a time chart illustrating the time variation of the locking detection signal when the door 10 is locked by the locking device 30. Portion 9G is a time chart illustrating the time variation of the detection signal (hereinafter, referred to as “fully closed detection signal”) of the fully closed detection switch 60 when the door 10 is locked by the locking device 30.

In FIG. 11, a specific example of the correlation between the protrusion of the plunger 34B and the inductance of the coil 34C of the solenoid 34 is the same as in FIG. 6. FIG. 12 shows a state in which the plunger 34B is stuck in a relatively large protrusion from the housing 34A. FIG. 14 shows a state in which the lock pin 31 is not inserted into the lock hole 32A even though the lock pin 31 can be inserted into the lock hole 32A due to sticking. FIG. 16 shows a state in which the lock pin 31 is inserted into the lock hole 32A and although the locking detection signal is switched to the ON signal, the insertion amount of the lock pin 31 into the lock hole 32A is relatively small due to sticking of the lock pin 31.

FIGS. 13, 15, and 17 include Portions 13A to 13G, 15A to 15G, and 17A to 17G, respectively. FIGS. 13A, 15A, and 17A are time charts illustrating the same contents as Portion 9A. Portions 13B to 13G are time charts illustrating an example (specifically, a specific example of the locking operation of the locking device 30 corresponding to FIG. 12 at the time of abnormality) of locking operation in an abnormal state of the locking device 30, and each shows a specific example of the time variation of the same observation object as in Portions 9B to 9G. Portions 15B to 15G are time charts illustrating another example (specifically, a specific example of the locking operation of the locking device 30 corresponding to FIG. 14 at the time of abnormality) of locking operation in an abnormal state of the locking device 30, and each shows a specific example of the time variation of the same observation object as in Portions 9B to 9G. Portions 17B to 17G are time charts illustrating another example (specifically, a specific example of the locking operation of the locking device 30 corresponding to FIG. 16 at the time of abnormality) of locking operation in an abnormal state of the locking device 30, and each shows a specific example of the time variation of the same observation object as in Portions 9B to 9G.

As shown in Portion 9G, when the door 10 reaches the fully closed position due to the closing operation of the door 10, the fully closed detection signal is switched from the off signal to the on signal. Immediately after that, as shown in Portion 9E, when the door 10 reaches the fully closed position, the lock pin 31 is lowered to the lock hole 32A by the biasing force caused by the biasing spring 33 and the self-weight of the lock pin 31. Then, the lock pin is inserted into the lock hole 32A and the lock detection signal is switched from the off signal to the on signal in the process until the lock pin 31 reaches the lower limit position.

As shown in Portion 9A, the driving circuit DRC shifts from the discharge operation to the monitoring operation controlled by the control circuit 82 at a time t21, which is assumed to be after the lock pin 31 reaches the lower limit position.

For example, the time t21 corresponds to the timing when a time greater than or equal to the maximum value of the time required for the lock pin 31 to descend to the lower limit position has elapsed based on the timing when the locking detection signal is switched from the off signal to the on signal. Also, the time t21 may be the timing when a time greater than or equal to the maximum value of the time required for the lock pin 31 to descend to the lower limit position has elapsed based on the timing when the fully closed detection signal is switched from the off signal to the on signal. Also, the time t21 may be the timing when a time greater than or equal to the maximum value of the time required for the lock pin 31 to descend to the lower limit position has elapsed based on the timing when the position of the door the fully closed position estimated based on the output of the encoder 40. Thus, the control circuit 82 can execute the monitoring operation of the driving circuit DRC after the locking operation of the door 10 by the locking device 30 is completed.

Specifically, in this example, the monitoring operation includes an operation mode 1, an operation mode 2, and an operation mode 3. First, at the time t21, the driving circuit DRC shifts from the discharge operation state to the operation mode 1 controlled by the control circuit 82. Controlled by the control circuit 82, the driving circuit DRC shifts from the operation mode 1 to the operation mode 2 at a time t22, and then shifts from the operation mode 2 to the operation mode 3 at a time t23. Then, at a time t24, the driving circuit DRC shifts from the operation mode 3 of the monitoring operation to the discharge operation state controlled by the control circuit 82.

In the operation mode 1 of the driving circuit DRC, controlled by the control circuit 82, an alternating voltage of a predetermined amplitude and a predetermined frequency with the zero reference of voltage is applied to the coil 34C, and an alternating current flows through the coil 34C. At this time, as shown in Portion 9D, the plunger 34B does not move. Therefore, the protrusion of the plunger 34B in the normal state of the locking device 30 is maintained at the initial value (i.e., the minimum value Amin).

In the operation mode 2 of the driving circuit DRC, a direct voltage of a constant voltage is applied to the coil 34C controlled by the control circuit 82, and a direct current flows through the coil 34C. At this time, the constant voltage is set to the extent that the plunger 34B can move and generate a thrust that prevents the vertical slider 35 from moving while the plunger 34B is in contact with the vertical slider 35. Thus, the plunger 34B moves upward by the amount of the vertical gap with the vertical slider 35, and is maintained in contact with the vertical slider 35. For example, as shown in FIG. 9D, during normal operation of the locking device 30, between the time t22 and the time t23, the plunger 34B moves by the amount of the very small gap with the vertical slider 35, and abuts against it. As shown in FIG. 9E, during normal operation of the locking device 30, since the vertical slider 35 does not move, the vertical position of the lock pin 31 does not change.

In the operation mode 3 of the driving circuit DRC, controlled by the control circuit 82, an alternating voltage of a predetermined amplitude and a predetermined frequency based on a predetermined voltage is applied, and an alternating current flows through the coil 34C. At this time, the constant voltage is set to such an extent that a thrust can be generated such that the vertical slider 35 cannot be moved while the plunger 34B is in contact with the vertical slider 35. The constant voltage is the same as the direct voltage in the operation mode 2, for example, as shown in FIG. 9B. Thus, in the operation mode 3 of the driving circuit DRC, the vertical position of the vertical slider 35 is maintained, and the plunger 34B is maintained in contact with the vertical slider 35.

For example, the door control device 80 executes the monitoring operation according to this example in accordance with the closing operation of the door 10 and the locking operation of the locking device 30 during the actual operation of the railway vehicle 1. Thus, for example, the door control device 80 can monitor the state of the locking device 30 in real time during the actual operation of the railway vehicle 1. In addition, the door control device 80 may execute the monitoring operation according to this example in accordance with the closing operation of the door 10 and the locking operation of the locking device 30 during the inspection of the railway vehicle 1 in the rail yard or the like.

For example, as shown in FIG. 10, the door control device 80 includes a monitoring part 801 as in the case of the first example (FIG. 6) described above.

In this example, the monitoring part 801 includes a plunger movement detecting part 8016 in addition to a current amplitude detecting part 8011, a mean current calculating part 8012, an inductance estimating part 8013, a protrusion estimating part 8014, and a determining part 8015. Hereinafter, in this example, description will be given mainly on parts different from those of the first example described above (FIG. and the same or corresponding parts may be omitted.

As in the first example described above, the inductance estimating part 8013 estimates the inductance L of the coil 34C in the operation modes 1 and 3 of the driving circuit DRC based on the correlation information, respectively.

The protrusion estimating part 8014 estimates the protrusion A of the plunger 34B in the operation modes 1 and 3 of the driving circuit DRC, respectively.

For example, as shown in FIG. 11, the correlation between the inductance L of the coil 34C and the protrusion A of the plunger 34B differs depending on the magnitude of the mean current I_{s_mean} of the coil 34C as described above. Therefore, the correlation information corresponding to the mean current I_{s_mean} of the operation mode 1 and the correlation information corresponding to the mean current I_{s_mean} of the operation mode 3 are prepared in advance, and the protrusion estimating part 8014 selects the correlation information corresponding to each of the operation modes 1 and 3. As in the first example described above, the estimated value of the inductance L of the coil 34C may be corrected by gain compensation or offset compensation before applying the correlation information in consideration of the variation of the inductance L of the coil 34C. Further, as in the first example described above, a plurality of correlation information corresponding to the same mean current I_{s_mean} may be prepared in consideration of the variation of inductance L of the coil 34C.

The plunger movement detecting part 8016 detects the presence or absence of relatively large movement of the plunger 34B in operation mode 2 of the driving circuit DRC. Specifically, the plunger movement detecting part 8016 detects the presence or absence of relatively large movement of the plunger 34B by detecting the presence or absence of a decrease in the current of the coil 34C due to the back electromotive force when a constant direct voltage is applied to the coil 34C in operation mode 2 of the driving circuit DRC. In other words, the plunger movement detecting part 8016 detects the presence or absence of relatively large movement of the plunger 34B to the extent that the direct current of the coil 34C decreases due to the back electromotive force.

The determining part 8015 determines the locking state of the door 10 by the locking device 30 based on the estimation result of the protrusion estimating part 8014 and the detection result of the plunger movement detecting part 8016.

For example, as shown in FIG. 12, a case is considered in which the plunger 34B is fixed in a state in which the protrusion A is relatively large in a state in which the energization of the coil 34C is stopped, and as a result, the movement of the vertical slider 35 is restricted, so that the lock pin 31 cannot move downward.

In this case, as shown in FIG. 13D, unlike the normal state of the plunger 34B (Portion 9D), the protrusion A of the plunger 34B is maintained in a relatively large state.

For example, the determining part 8015 determines whether the estimated value of the protrusion A of the plunger 34B in the operation mode 1 of the driving circuit DRC estimated by the protrusion estimating part 8014 is smaller than the threshold Ath2. As shown in FIG. 11, the threshold Ath2 is a positive value (Ath2>0) and is set in advance as a value between the maximum value Amax and the minimum value Amin of the protrusion of the plunger 34B (specifically, 0≤Amin<Ath2<Amax).

For example, the threshold Ath2 is set as an upper limit value of the protrusion A of the plunger 34B to achieve a state in which the lock pin 31 is inserted into the lock hole 32A and the locking detection signal is an ON signal. Specifically, the threshold Ath2 is set to the sum (addition value) of the initial value of the protrusion of the plunger 34B, the gap between the plunger 34B and the vertical slider 35, and the vertical difference between the lower limit position of the lock pin 31 and the position at which the locking detection signal is switched to an ON signal. This is because the locking detection signal is switched to an ON signal when the lock pin 31 is inserted into the lock hole 32A to some extent from the viewpoint of safety. Thus, when the estimated value of the protrusion A of the plunger 34B in the operation mode 1 of the driving circuit DRC is equal to or greater than the threshold Ath2, the determining part 8015 can determine that the door 10 is not locked normally due to the sticking of the plunger 34B. Conversely, when the estimated value of the protrusion A of the plunger 34B in the operation mode 1 of the driving circuit DRC is smaller than the threshold Ath2, the determining part 8015 can determine that there is no abnormality in the position of the plunger 34B due to sticking or the like.

Hereinafter, the condition that the protrusion A of the plunger 34B in the operation mode 1 of the driving circuit DRC is smaller than the threshold Ath2 may be conveniently referred to as “a first determination condition”.

For example, as shown in FIG. 14, the case where the lock pin 31 is fixed in a state where the lower end of the lock pin 31 is located above the opening of the lock hole 32A due to sticking or the like, and as a result, the lock pin 31 is not inserted into the lock hole 32A is considered.

In this case, as shown in Portion 15E, unlike in the normal state (Portion 9E), the lock pin 31 is located above the lower limit position, which is relatively large. As a result, as shown in FIG. 14, when the locking operation of the locking device 30 is completed, the vertical clearance between the vertical slider 35 connected to the lock pin 31 and the normal plunger 34B that is not energized is extremely large. Therefore, as shown in Portions 15C and 15D, the amount of protrusion A of the plunger 34B is greatly increased by the application of direct voltage to the coil 34C by the operation mode 2 of the driving circuit DRC, and the current of the coil 34C is decreased by the back electromotive force.

For example, when the plunger movement detecting part 8016 detects a relatively large movement of the plunger 34B under the assumption that the first determination condition is satisfied, the determining part 8015 can determine that the door 10 is not normally locked due to the sticking of the lock pin 31 or the like. Additionally, the determining part 8015 determines that there is no major abnormality in the position of the lock pin 31 if the plunger movement detecting part 8016 does not detect a relatively large movement of the plunger 34B under the assumption that the first determination condition is satisfied. The major abnormality in the position of the lock pin 31 means, for example, an abnormality in a state where the lock pin 31 is not inserted into the lock hole 32A at all.

Hereinafter, the detection of a relatively large movement of the plunger 34B in the operation mode 2 of the driving circuit DRC may be conveniently referred to as “a second determination condition”.

In addition, for example, as shown in FIG. 16, a case is considered in which the lower end of the lock pin 31 is inserted into the lock hole 32A and the locking detection signal is switched to the ON signal, but the lock pin 31 is not fully moved to the lower limit position due to sticking or the like.

In this case, as shown in FIG. 16, between the vertical slider 35 connected to the lock pin 31 and the normal plunger 34B that is not energized, there is a vertical gap larger than when the position of the lock pin 31 is normal. However, the gap is smaller than in the case of FIG. 14. Therefore, as shown in Portions 17C and 17D, although the protrusion A of the plunger 34B increases by the application of direct voltage to the coil 34C by the operation mode 2 of the driving circuit DRC, the current of the coil 34C does not decrease due to the back electromotive force.

For example, the determining part 8015 determines whether or not the estimated value of the protrusion A of the plunger 34B in the operation mode 3 of the driving circuit DRC estimated by the protrusion estimating part 8014 is smaller than the threshold Ath2 under the assumption that the first determination condition is satisfied. Thus, when the first determination condition is satisfied and the estimated value of the protrusion A of the plunger 34B in the operation mode 3 of the driving circuit DRC is equal to or greater than the threshold Ath2, the determining part 8015 can determine that the lock pin 31 is not fully lowered due to sticking or the like and the door is not normally locked. Conversely, when the estimated value of the protrusion A of the plunger 34B in the operation mode 3 of the driving circuit DRC is smaller than the threshold Ath2, the determining part 8015 can determine that there is no abnormality in the position of the lock pin 31 when the locking operation of the locking device 30 is completed. Therefore, if the first determination condition is satisfied and the protrusion A of the plunger 34B in the operation mode 3 of the driving circuit DRC is smaller than the threshold Ath2, the determining part 8015 can determine that the door 10 is normally locked.

Hereinafter, the fact that the protrusion A of the plunger 34B in the operation mode 3 of the driving circuit DRC is smaller than the threshold Ath2 may be conveniently referred to as “a third determination condition”.

The determining part 8015 outputs to the outside a flag indicating the determination result, that is, a locking OK flag indicating that the door 10 is normally locked or a locking NG flag indicating that the door 10 is not normally locked.

The determining part 8015 outputs to the outside a flag indicating the determination result, that is, a locking OK flag indicating that the door 10 is normally locked, or a locking NG flag indicating that the door 10 is not normally locked.

For example, the determining part 8015 transmits a flag indicating the determination result to the host device of the railway vehicle 1. Thus, the host device can output the determination result from a display device or a sound output device in the operator's cabin or the conductor's cabin of the railway vehicle 1. Thus, it is possible to notify the operator, conductor, or other crew member of the railway vehicle 1 whether or not the door 10 is normally locked.

In addition to the determination result of the determining part 8015, the determining part 8015 may also transmit to the host device various information (incidental information) obtained by the monitoring part 801 during the monitoring operation of the driving circuit DRC. The incidental information includes not only information calculated or estimated by each function of the monitoring part 801, but also source information for obtaining the information. Thus, the host device can store a log composed of the combination of the determination result and the incidental information in a storage device mounted on the railway vehicle 1, or can transmit the log to an external device and store the log in the external device. Therefore, for example, an inspector can confirm the state of the locking operation of the door 10 by the locking device 30 during operation of the railway vehicle 1 after the fact by checking the accumulated log. Further, the door control device 80, the host device, or the external device may analyze the accumulated logs and predict the deterioration state and the life of the lock pin 31, the solenoid 34, and the like of the locking device 30.

Thus, in this example, after the locking operation of the driving circuit DRC is completed, the door control device 80 executes the monitoring operation up to the operation mode 1 to 3. Based on the voltage and current of the coil 34C during the monitoring operation, the inductance of the coil 34C is estimated, and the movement of the plunger 34B is detected, so that whether or not the door 10 is normally locked can be monitored.

### Second Example of Control Processing of Door Control Device

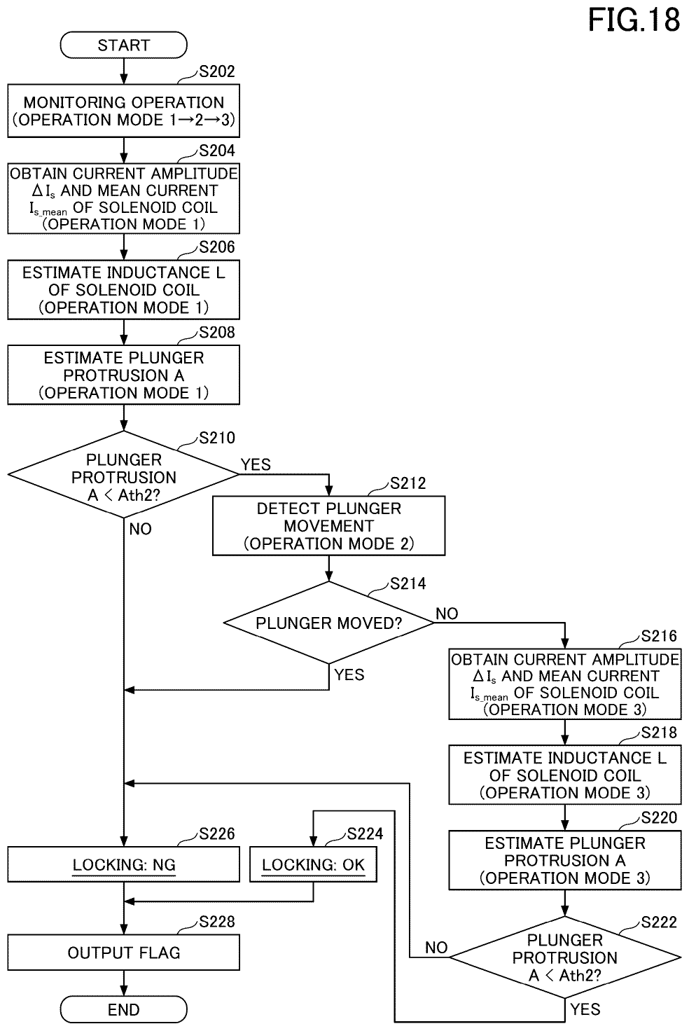

Next, a second example of control processing of the door control device 80 will be described with reference to FIG. 18. Specifically, a specific example of control processing of the door control device 80 including a processing flow corresponding to the second example of the monitoring method of the state of the locking device 30 will be described.

FIG. 18 is a flowchart schematically illustrating the second example of control processing of the door control device 80.

This flowchart is executed by, for example, the arrival of a predetermined timing at which it can be determined that the locking operation of the locking device 30 is completed as a trigger. The predetermined timing is, for example, the timing at which a predetermined time elapses after the locking detection signal or the fully closed detection signal is switched from the OFF signal to the ON signal.

As shown in FIG. 18, in a step S202, the control circuit 82 of the door control device 80 controls the inverter circuit 81 and causes the driving circuit DRC to execute the monitoring operation in the order of operation mode 1, operation mode 2, and operation mode 3. At this time, the control circuit 82 applies an alternating voltage to the coil 34C in operation modes 1 and 3, and applies a direct voltage to the coil 34C in operation mode 2, as described above.

In a step S204, the monitoring part 801 of the door control device 80 obtains the current amplitude ΔIₛ and the mean current I_{s_mean} of the coil 34C of the solenoid 34 in operation mode 1 by the functions of the current amplitude detecting part 8011 and the mean current calculating part 8012.

When the processing of the step S204 is completed, the door control device 80 proceeds to a step S206.

In the step S206, the monitoring part 801 of the door control device 80 estimates the inductance L of the solenoid coil (coil 34C) in operation mode 1 by the function of the inductance estimating part 8013.

When the processing of the step S206 is completed, the door control device 80 proceeds to a step S208.

In the step S208, the monitoring part 801 of the door control device 80 estimates the protrusion A of the plunger 34B in operation mode 1 by the function of the protrusion estimating part 8014.

When the processing of the step S208 is completed, the door control device 80 proceeds to a step S210.

In the step S210, the monitoring part 801 of the door control device 80 determines whether the estimated value of the protrusion A of the plunger 34B in operation mode 1 is smaller than the threshold Ath2 by the function of the determining part 8015. When the estimated value of the protrusion A of the plunger 34B in the operation mode 1 is smaller than the threshold Ath2, the monitoring part 801 determines that there is no abnormality related to the position of the plunger 34B, and proceeds to a step S212. Conversely, when the estimated value of the protrusion A of the plunger 34B in the operation mode 1 is greater than or equal to the threshold Ath2, the monitoring part 801 determines that there is abnormality related to the position of the plunger 34B, and proceeds to a step S226.

In the step S212, the monitoring part 801 of the door control device 80 performs processing for detecting a relatively large movement of the plunger 34B in the operation mode 2 by the function of the plunger movement detecting part 8016.

When the processing of the step S212 is completed, the door control device 80 proceeds to a step S214.

In the step S214, the monitoring part 801 of the door control device 80 determines whether or not a relatively large movement of the plunger 34B in the operation mode 2 is detected by the function of the determining part 8015. When a relatively large movement of the plunger 34B in the operation mode 2 is detected, the monitoring part 801 determines that there is a large abnormality in the position of the lock pin 31 and proceeds to a step S226. Conversely, when a relatively large movement of the plunger 34B in the operation mode 2 is not detected, the monitoring part 801 determines that there is no large abnormality in the position of the lock pin 31 and proceeds to a step S216.

In the step S216, the monitoring part 801 of the door control device 80 obtains the current amplitude ΔIₛ and the mean current I_{s_mean} of the coil 34C of the solenoid 34 in the operation mode 3 by the functions of the current amplitude detecting part 8011 and the mean current calculating part 8012.

When the processing of the step S216 is completed, the door control device 80 proceeds to a step S218.

In the step S218, the monitoring part 801 of the door control device 80 estimates the inductance L of the solenoid coil (coil 34C) in the operation mode 3 by the function of the inductance estimating part 8013.

When the processing of the step S218 is completed, the door control device 80 proceeds to a step S220.

In the step S220, the monitoring part 801 of the door control device 80 estimates the protrusion A of the plunger 34B in the operation mode 3 by the function of the protrusion estimating part 8014.

When the processing of the step S220 is completed, the door control device 80 proceeds to a step S222.

In the step S222, the monitoring part 801 of the door control device 80 determines whether or not the estimated value of the protrusion A of the plunger 34B in the operation mode 3 is smaller than the threshold Ath2 by the function of the determining part 8015. When the estimated value of the protrusion A of the plunger 34B in the operation mode 3 is smaller than the threshold Ath2, the monitoring part 801 determines that there is no abnormality related to the position of the lock pin 31, and proceeds to a step S224. Conversely, when the estimated value of the protrusion A of the plunger 34B in the operation mode 3 is equal to or larger than the threshold Ath2, the monitoring part 801 determines that there is an abnormality related to the position of the lock pin 31, and proceeds to a step S226.

In the step S224, the monitoring part 801 of the door control device 80 determines that the door 10 is normally locked (i.e., “Lock: OK”) by the locking device 30 by the function of the determining part 8015.

Conversely, in the step S226, the monitoring part 801 of the door control device 80 determines that the door 10 is not normally locked by the locking device 30 by the function of the determining part 8015.

When the processing of the step S224 or the step S226 is completed, the door control device 80 proceeds to a step S228.

In the step S228, the monitoring part 801 of the door control device 80 outputs to the outside a flag indicating the result of determining whether or not the door 10 is normally locked by the locking device 30 by the function of the determining part 8015.

When the processing of the step S228 is completed, the door control device 80 completes the process of the present flowchart.

### Second Example of Locking Device

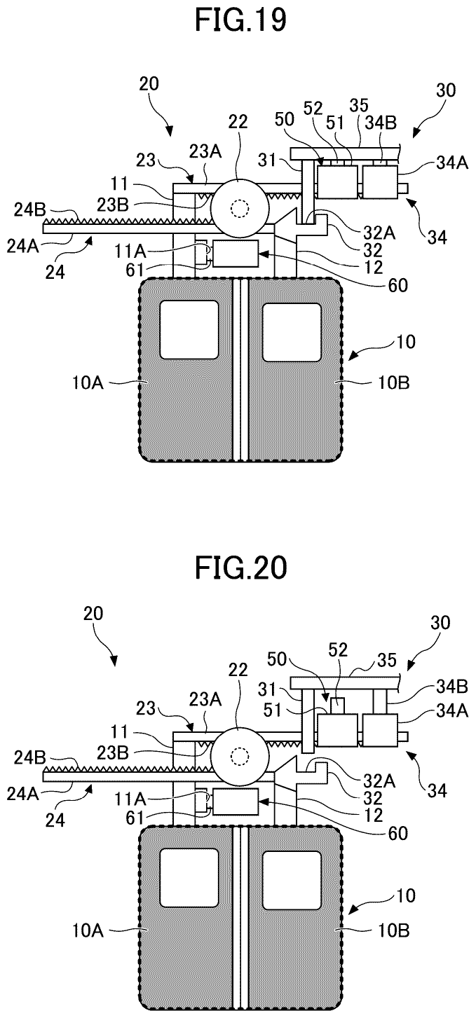

Next, a second example of the locking device 30 according to the present embodiment will be described with reference to FIGS. 19 to 21.

Hereinafter, in this example, the same or corresponding components as those of the first example of the locking device 30 and the first example of the driving circuit DRC are denoted by the same reference numerals, and the description will be given mainly on the parts different from those of the first example, and the description of the parts same or corresponding to those of the first example may be omitted.

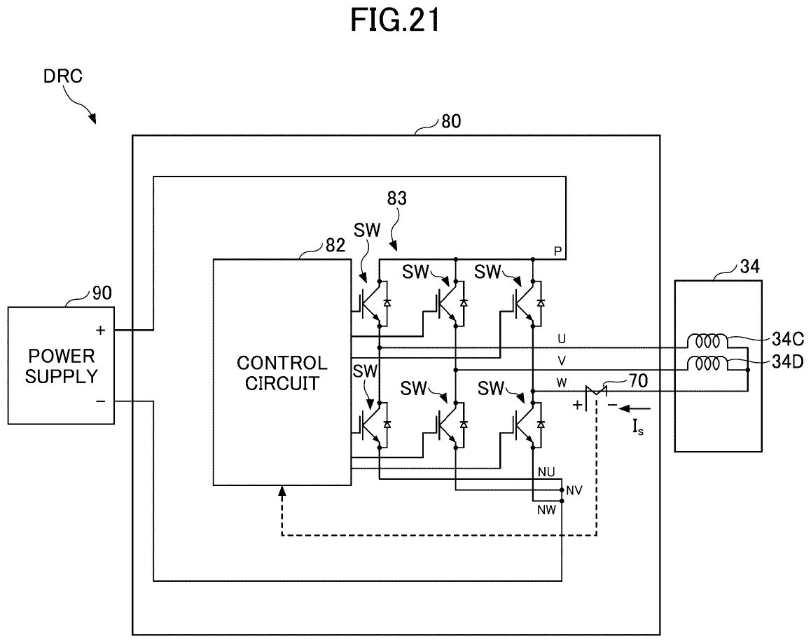

FIGS. 19 and 20 are drawings illustrating the second example of the locking device 30 of the door 10. FIG. 21 is a drawing illustrating the second example of the driving circuit DRC for the locking device 30.

Specifically, FIG. 19 is a drawing illustrating the second example of the locking device 30 when the door 10 is in the fully closed position and the door 10 is locked by the locking device 30. FIG. 20 is a drawing illustrating the second example of the locking device 30 when the door 10 is in the fully closed position and the door 10 is unlocked by the locking device 30. FIG. 21 is a drawing illustrating a specific example of the driving circuit DRC for electrically driving the locking device 30 shown in FIGS. 19 and 20.

As shown in FIGS. 19 and 20, in this example, the door 10 is a double sliding door and includes door panels 10A and 10B. In this example, the door driving mechanism 20 includes a motor 22 and rack parts 23 and 24.

The motor 22 is a rotary electric motor. Operation of the motor 22 is controlled by the door control device 80. The motor 22 is driven by, for example, three-phase alternating current drive power supplied through the door control device 80.

The rack part 23 is connected to the door panel 10A by a connecting member 11 and is disposed above the door panels 10A and 10B. The rack part 23 includes a rack bar 23A and rack teeth 23B.

The rack bar 23A is disposed above the door panel 10A so as to extend in the longitudinal direction of the railway vehicle 1, and a rack teeth 23B is disposed on its lower surface. The rack bar 23A is disposed above the door opening of the vehicle body of the railway vehicle 1 slightly above the rotating shaft of a motor 22 whose rotating shaft is disposed along the width direction (i.e., in the lateral direction) of the railway vehicle 1. Thus, the rack teeth 23B on the lower surface of the rack bar 23A can be engaged with a pinion gear (not shown) arranged coaxially with the rotating shaft of the motor 22. Therefore, the rack bar 23A can be moved in the longitudinal direction of the railway vehicle 1 in accordance with the rotation of the motor 22, and as a result, the opening and closing operation of the door panel 10A can be achieved.

The rack part 24 is connected with the door panel 10B by a connecting member 12, and is arranged above the door panels 10A and 10B. The rack part 24 includes a rack bar 24A and rack teeth 24B.

The rack bar 24A is provided above the door panel 10B so as to extend in the longitudinal direction of the railway vehicle 1, and a rack teeth 24B is provided on the upper surface thereof. The rack bar 24A is arranged above the door opening of the vehicle body of the railway vehicle 1 slightly below the rotational axis of the motor 22 whose rotational axis is arranged along the width direction (i.e., in the lateral direction) of the railway vehicle 1. Thus, a pinion gear (not shown) arranged coaxially with the rotational axis of the motor 22 can be engaged with the rack teeth 24B on the upper surface of the rack bar 24A. Therefore, the rack bar 24A can be moved in the longitudinal direction of the railway vehicle 1 in accordance with the rotation of the motor 22, and as a result, the opening and closing operation of the door panel 10B can be achieved.

The movement of the door panels 10A and 10B in the longitudinal direction of the railway vehicle 1 is guided by a slide rail provided around the door opening of the railway vehicle 1, respectively. In addition, the connecting member 11 is provided with a pressing part 11A which can press the actuator 61 of the fully closed detection switch 60. Thus, when the door panel 10A is in the fully closed position, the fully closed detection switch 60 can be turned on by pressing the actuator 61 of the fully closed detection switch 60 by the pressing part 11A. Additionally, when the door panel 10A moves in the open direction from the fully closed position, the pressing part 11A moves in the direction away from the actuator 61, and the fully closed detection switch 60 can be turned off. Therefore, the fully closed detection switch 60 can detect the fully closed state of the door 10.

In this example, the locking device 30 includes a lock pin 31, an opening and closing interlocking member 32, a solenoid 34, and a vertical slider 35.

The lock pin 31 has its upper end connected to the vertical slider 35, and is supported directly or indirectly on the vehicle body of the railway vehicle 1 so that it can move vertically within a predetermined range (range of motion) together with the vertical slider.

The opening and closing interlocking member 32 is provided at the end of the door 10 of the rack part 24 in the opening direction and at the upper end of the connecting member 12, and moves in the opening and closing directions interlocked with the opening and closing operation of the door panel 10B. As in the first example described above, the opening and closing interlocking member 32 is disposed below the lock pin 31 and has a lock hole 32A.

The lock hole 32A is a recess provided on the upper surface of the opening and closing interlocking member 32, and is disposed so that the lock pin 31 can be inserted from above in the fully closed position of the door 10. As shown in FIGS. 19 and 20, for example, the lock hole 32A has an opening only on the upper side of the opening and closing interlocking member 32. The lock hole 32A may penetrate the opening and closing interlocking member 32 in the vertical direction.

The solenoid 34 is a self-holding type and includes a housing 34A and a plunger 34B, a coil 34C for unlocking, and a coil 34D for locking housed in the housing 34A.

When a current flows through the coil 34C in the state at the lower limit position, the plunger 34B moves upward by being attracted by the fixed core magnetized by the coil 34C, and the upper end thereof largely protrudes upward from the housing 34A. Since the plunger 34B is attracted by a permanent magnet built in the housing 34A for holding the unlocked state, the plunger 34B can be maintained in the upper limit position even after the energization of the coil 34C is completed.

Further, when a current flows through the coil 34D in the state of the upper limit position, the plunger 34B is attracted by the fixed core magnetized by the coil 34D, and moves downward and is drawn into the housing 34A. Since the plunger 34B is attracted by a permanent magnet built in the housing 34A for holding the locked state, the plunger 34B can be maintained in the lower limit position even after the energization of the coil 34D is completed.

For example, as shown in FIG. 21, the driving circuit DRC of the locking device 30 incorporates a power supply 90, coils 34C and 34D, and an inverter circuit 83 built in the door control device 80.

One end of the coil 34C is connected to the U-phase output of the inverter circuit 83, and the other end is connected to the W-phase output of the inverter circuit 83. One end of the coil 34D is connected to the V-phase output of the inverter circuit 83, and the other end is connected to the W-phase output of the inverter circuit 83.

The inverter circuit 83, controlled by the control circuit 82, can apply a voltage in a predetermined pattern to either the coil 34C or the coil 34D, using the power supplied from the power supply 90, to energize them. For example, the control circuit 82 can control the current of the coils 34C and 34D by appropriately turning ON or OFF the switching element SW of the inverter circuit 83 by the PWM signal in response to the current command Ic.

The current sensor 70 is arranged to detect the current of the W-phase output of the inverter circuit 83. Thus, the current sensor 70 detects the current Is of the coils 34C and 34D, and the detection signal is received into the control circuit 82. Thus, the control circuit 82 can feedback control the current Is of the coils 34C and 34D based on the detection signal of the current sensor 70.

As in the first example described above, the vertical slider 35 is directly or indirectly attached to the vehicle body of the railway vehicle 1, and can be moved in the vertical direction with respect to the vehicle body as a fixed part as a reference. The vertical slider 35 is arranged so as to cover the upper part of the lock pin 31 and the solenoid 34, and is directly or indirectly connected to the lock pin 31 through another member, and can be abutted by the plunger 34B. Thus, the locking device 30 can move the vertical slider 35 upward by greatly projecting the plunger 34B of the solenoid 34 upward from the housing 34A, and as a result, move the lock pin 31 upward. Therefore, by energizing the coil 34C in the fully closed position of the door 10, the solenoid 34 can release the state in which the lower end of the lock pin 31 is inserted into the lock hole 32A, and shift the door 10 from the locked state to the unlocked state. Moreover, by moving downward from the state in which the plunger 34B of the solenoid 34 protrudes widely, the locking device 30 can move the vertical slider 35 downward by the self-weight, and as a result, move the lock pin 31 downward. Therefore, by energizing the coil 34D in the fully closed position of the door 10, the solenoid 34 can insert the lower end of the lock pin 31 into the lock hole 32A, and shift the door 10 from the unlocked state to the locked state.

As shown in FIGS. 19 and 20, the locking detection switch 50 is provided below the vertical slider 35. The locking detection switch 50 includes a body part 51 and an actuator part 52.

The locking detection switch 50 is a momentary switch, and a biasing force acts on the actuator part 52 so as to maintain the state in which the actuator part 52 largely protrudes upward from the body part 51, that is, the OFF state.

When the vertical slider 35 is in the lower limit position, the lower surface of the vertical slider 35 comes into contact with the actuator part 52, and the actuator part 52 is pressed by the self-weight of the vertical slider 35. Thus, the actuator part 52 is pushed into the body part 51 by the vertical slider 35 against the biasing force, and as a result, the locking detection switch 50 can be maintained in the ON state. Conversely, when the vertical slider 35 is in the upper stroke end (i.e., the upper limit position) in the state of being pushed up by the plunger 34B, the lower surface of the vertical slider 35 does not come into contact with the actuator part 52. Thus, the locking detection switch 50 can be maintained in the OFF state by the biasing force acting on the actuator part 52. The locking detection switch 50 can shift from the OFF state to the ON state when the lock pin 31 connected to the vertical slider 35 is inserted into the lock hole 32A and the door 10 shifts from the unlocked state to the locked state. The locking detection switch 50 can shift from the ON state to the OFF state in accordance with the upward movement of the plunger 34B and the shift from the state in which the lock pin 31 is inserted into the lock hole 32A to the state in which the insertion is released.

### Third Example of Locking Device State Monitoring Method

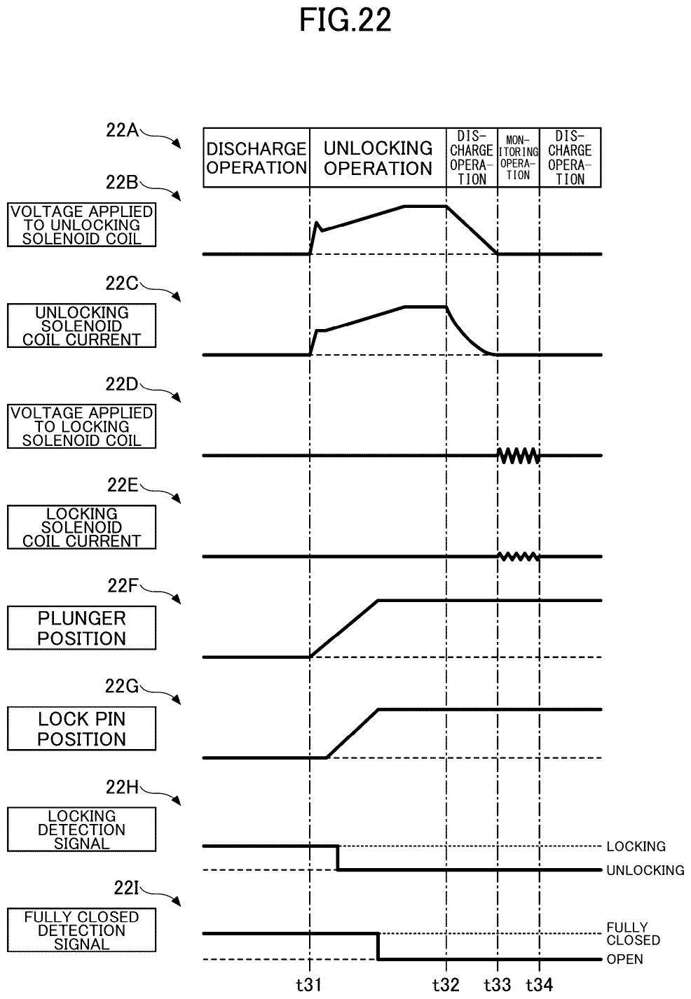

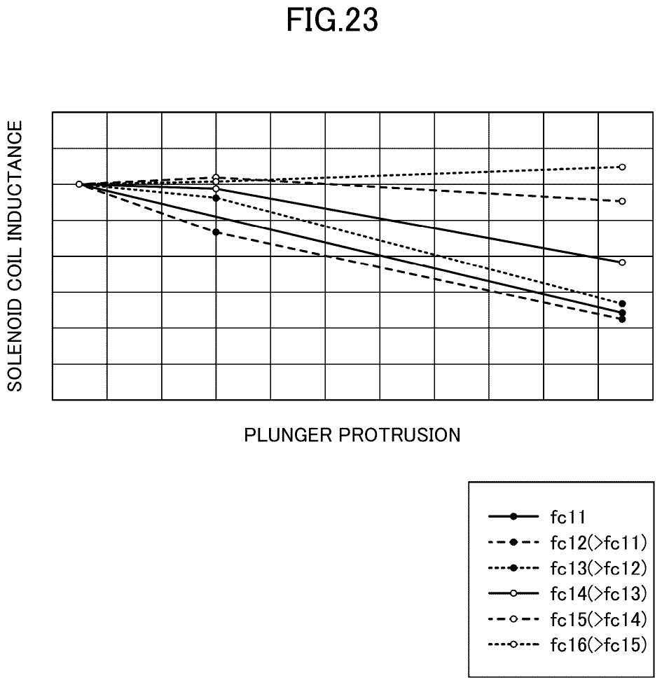

Next, with reference to FIGS. 22 and 23, a third example of monitoring the state of the locking device 30 by the door control device 80 will be described.

Hereinafter, in this example, the configuration of FIG. 19, the locking device 30 shown in FIG. 20, and the driving circuit DRC shown in FIG. 21 is assumed. In this example, the configuration related to the state monitoring function of the locking device 30 may be the same as that of the first example (FIG. 6). Therefore, in this example, FIG. 6 is used and the functional block diagram showing the configuration thereof is omitted. In addition, in this example, the description will be focused on the parts different from the first and second examples of the monitoring method described above, and the same or corresponding parts as the first and second examples of the monitoring method described above may be omitted.

FIG. 22 is a time chart describing the third example of the method for monitoring the state of the locking device 30. FIG. 23 is a drawing illustrating an example of the correlation between the protrusion A of the plunger 34B and the inductance L of the locking solenoid coil (coil 34D).

Specifically, FIG. 22 includes Portions 22A to 221. Portion 22A is a time chart showing the flow of the operation of the driving circuit DRC when the locking device 30 unlocks the door 10. Portions 22B to 221 are time charts showing an example of the unlocking operation of the locking device 30 when the locking device 30 is in a normal state. Portion 22B is a time chart showing the time variation of the applied voltage of an unlocking solenoid coil (coil 34C) when the locking device 30 unlocks the door 10. Portion 22C is a time chart showing the time variation of the current of the unlocking solenoid coil (coil 34C) when the locking device 30 unlocks the door 10. Portion 22D is a time chart showing the time variation of the applied voltage of the locking solenoid coil (coil 34D) when the locking device 30 unlocks the door 10. Portion 22E is a time chart showing the time variation of the current of the locking solenoid coil (coil 34D) when the locking device 30 unlocks the door 10. Portion 22F is a time chart showing the time variation of the vertical position of the plunger 34B when the locking device 30 unlocks the door 10. Portion 22G is a time chart showing the time variation of the vertical position of the lock pin 31 when the locking device 30 unlocks the door 10. Portion 22H is a time chart showing the time variation of the locking detection signal when the locking device 30 unlocks the door 10. Portion 22I is a time chart showing the time variation of the fully closed detection signal when the locking device 30 unlocks the door 10.

FIG. 23 shows the correlation between the protrusion A of the plunger 34B and the inductance L of the solenoid coil (coil 34D) when the frequency fc of the alternating voltage applied to the coil 34D has 6 predetermined values fc1 to fc6.

As shown in Portion 22A, at a time t31, controlled by the control circuit 82, the driving circuit DRC shifts from a discharge operation to an operation for unlocking the door 10 (unlocking operation). In the discharge operation of the driving circuit DRC, the energy accumulated in the coils 34C and 34D is discharged by turning on all the switching elements SW of the lower arm of the inverter circuit 83.

As shown in Portions 22B and 22C, in the unlocking operation of the driving circuit DRC, a direct voltage of a predetermined pattern is applied to the coil 34C controlled by the control circuit 82, and a direct current of a predetermined pattern is applied to the coil 34C under feedback control. As a result, at the time t31, as shown in Portion 22F, the plunger 34B starts moving upward, and then, as shown in Portion 22G, the plunger 34B comes into contact with the vertical slider 35, and the lock pin 31 starts moving upward. After that, as shown in Portion 5H, the locking detection signal is switched from ON to OFF as the plunger 34B moves upward.

As shown in Portion 22F, the plunger 34B continues moving upward by energizing the coil 34C, and reaches its upper limit position. As a result, as shown in FIG. 22G, the lock pin 31 reaches the upper limit position as the plunger 34B moves upward, and the locking device 30 can achieve the fully unlocked state of the door 10.

As shown in Portion 22A, after the plunger 34B reaches the upper limit position, at a time t32, the driving circuit DRC shifts to the discharge operation state controlled by the control circuit 82.

As shown in Portions 22B and 22C, in the discharge operation state of the driving circuit DRC after the time t32, the applied voltage and current of the coil 34C decrease toward zero. Thereafter, when the applied voltage and current of the coil 34C converge to zero, the driving circuit DRC shifts from the discharge operation to the operation for monitoring the state of the locking device 30 (monitoring operation) controlled by the control circuit 82 at a time t33.

As shown in Portions 22D and 22F, in the monitoring operation of the driving circuit DRC, controlled by the control circuit 82, an alternating voltage of a predetermined a amplitude and predetermined frequency with the zero reference of voltage is applied to the locking solenoid coil (coil 34D), and an alternating current flows through the coil 34D. At this time, since the DIRECT CURRENT component of the alternating voltage applied to the coil 34D is zero, the position of the plunger 34B does not change as shown in Portion 22F.

As shown in Portion 22A, when the monitoring operation is completed, the driving circuit DRC shifts to the discharge operation at a time t34.

For example, the door control device 80 executes the unlocking operation and the monitoring operation according to this example in accordance with the opening operation of the door 10 during the actual operation of the railway vehicle 1. Thus, for example, the door control device 80 can monitor the state of the locking device 30 in real time during the actual operation of the railway vehicle 1. In addition, the door control device 80 may execute the unlocking operation and the monitoring operation according to this example in accordance with the opening operation of the door 10 during the inspection of the railway vehicle 1 in the rail yard or the like.

For example, as shown in FIG. 6, the door control device 80 includes a monitoring part 801 as a function part for monitoring the state of the locking device 30 as in the first example described above.

As in the first example described above, the monitoring part 801 includes a current amplitude detecting part 8011, a mean current calculating part 8012, an inductance estimating part 8013, a protrusion estimating part 8014, and a determining part 8015. Hereinafter, the description of this example will focus on the different parts from the first example described above (FIG. 6), and the same or corresponding parts may be omitted.

The current amplitude detecting part 8011 detects the current amplitude ΔIₛ of the locking solenoid coil (coil 34D) during the monitoring operation of the driving circuit DRC based on the output of the current sensor 70 and the carrier frequency of the PWM signal of the inverter circuit 83.

The mean current calculating part 8012 calculates the mean value (mean current I_{s_mean}) of the current Iₛ of the locking solenoid coil (coil 34D) during the monitoring operation of the driving circuit DRC based on the output of the current sensor 70 and the carrier frequency of the PWM signal of the inverter circuit 83.

The inductance part estimating 8013 estimates the inductance L of the coil 34D during the monitoring operation of the driving circuit DRC based on the current amplitude ΔIₛ, the mean current I_{s_mean}, and the applied voltage Vₛ of the locking solenoid coil (coil 34D).

The protrusion estimating part 8014 estimates the protrusion A of the plunger 34B during the monitoring operation of the driving circuit DRC based on the estimated value of the inductance L output from the inductance estimating part 8013.

For example, the protrusion estimating part 8014 estimates the protrusion A of the plunger 34B from the estimated value of the inductance L using information (correlation information) representing the correlation between the inductance L of the coil 34D and the protrusion A of the plunger 34B.

For example, as shown in FIG. 23, the correlation between the inductance L of the coil 34D and the protrusion A of the plunger 34B differs depending on the frequency of the applied voltage of the coil 34D. Therefore, the correlation information corresponding to the frequency of the applied voltage of the coil 34D during the monitoring operation of the driving circuit DRC is prepared in advance. As in the first and second examples described above, the estimated value of the inductance L of the coil 34D may be corrected by gain compensation or offset compensation before applying the correlation information in consideration of the variation of the inductance L of the coil 34D. Also, as in the first and second examples described above, a plurality of correlation information corresponding to the same frequency may be prepared in consideration of the variation of the inductance L of the coil 34D.

The determining part 8015 determines the unlocking state of the door 10 by the locking device 30 based on the estimated value of the protrusion A of the plunger 34B during the monitoring operation of the driving circuit DRC estimated by the protrusion estimating part 8014.

For example, the determining part 8015 determines whether the estimated value of the protrusion A of the plunger 34B is equal to or greater than the threshold Ath3. The threshold Ath3 is a positive value (Ath3>0) and is preset as a value between the maximum value Amax and the minimum value Amin of the protrusion A of the plunger 34B (specifically, 0≤Amin<Ath3<Amax).

For example, the threshold Ath3 is set as the lower limit value of the protrusion A of the plunger 34B to achieve the state in which the lock pin 31 is not inserted into the lock hole 32A, similar to the threshold Ath1 of the first example described above. Specifically, the threshold Ath3 is set to the sum (addition value) of the initial value of the protrusion of the plunger 34B, the gap between the plunger 34B and the vertical slider 35, and the vertical lap amount between the lock pin 31 and the lock hole 32A in the locked state of the door 10. The initial value of the protrusion of the plunger 34B means the upward protrusion from the housing 34A when the plunger 34B is in the lower limit position in the normal state of the solenoid 34, and corresponds to the minimum value Amin described above. The gap between the plunger 34B and the vertical slider 35 means the vertical gap between the vertical slider 35 at the lower limit position and the plunger 34B at the lower limit position. The vertical lap amount between the lock pin 31 and the lock hole 32A in the locked state of the door 10 means the vertical insertion depth of the lock pin 31 in the lock hole 32A when the lock pin 31 is in the lower limit position. Thus, when the protrusion A of the plunger 34B is equal to or greater than the threshold Ath3, the determining part 8015 can determine that the door 10 is normally unlocked because the lower end of the lock pin 31 is at the same or higher upper position than the opening of the lock hole 32A. Conversely, when the estimated protrusion A of the plunger 34B is less than the threshold Ath3, the determining part 8015 can determine that the door 10 is not normally unlocked by the locking device 30.

As in the first example described above, the determining part 8015 outputs to the outside a flag indicating the determination result, that is, an unlocking OK flag indicating that the door 10 is normally unlocked, or an unlocking NG flag indicating that the door 10 is not normally unlocked.

Thus, in this example, after the unlocking operation of the driving circuit DRC is completed, the door control device 80 causes the driving circuit DRC to execute a monitoring operation for applying an alternating voltage to the locking solenoid coil (coil 34D). Then, the door control device 80 can monitor whether the door 10 is normally unlocked by estimating the inductance of the coil 34D based on the voltage and current of the coil 34D during the monitoring operation.

### Third Example of Control Processing of Door Control Device

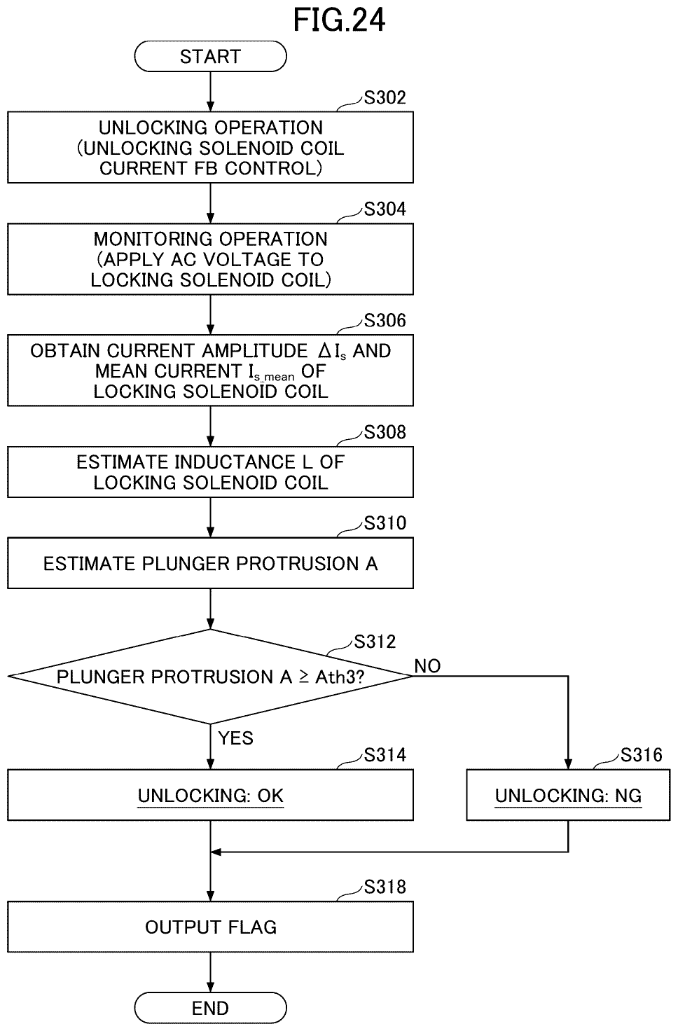

Next, a third example of control processing of the door control device 80 will be described with reference to FIG. 24. Specifically, a specific example of control processing of the door control device 80 including a processing flow corresponding to the third example of the monitoring method of the state of the locking device 30 will be described.

FIG. 24 is a flowchart schematically illustrating the third example of control processing of a door control device 80.

This flowchart starts when, for example, a command from the host device instructing to open the door 10 is input to the door control device 80.

As shown in FIG. 24, in a step S302, the control circuit 82 of the door control device 80 controls the inverter circuit 83 to cause the driving circuit DRC to execute the unlocking operation. At this time, the control circuit 82 performs current feedback control of the unlocking solenoid coil (coil 34C) according to a predetermined current pattern based on the output of the current sensor 70.

When the processing of the step S302 is completed, the door control device 80 proceeds to a step S304.

In the step S304, the control circuit 82 of the door control device 80 controls the inverter circuit 83 to cause the driving circuit DRC to execute the monitoring operation. At this time, the control circuit 82 applies an alternating voltage to the locking solenoid coil (coil 34D) by the driving circuit DRC as described above.

When the processing of the step S304 is completed, the door control device 80 proceeds to a step S306.

In the step S306, the monitoring part 801 of the door control device 80 obtains the current amplitude ΔIₛ and the mean current I_{s_mean} of the locking solenoid coil (coil 34D) during the monitoring operation by the functions of the current amplitude detecting part 8011 and the mean current calculating part 8012.

When the processing of the step S306 is completed, the door control device 80 proceeds to a step S308.

In the step S308, the monitoring part 801 of the door control device 80 estimates the inductance L of the locking solenoid coil (coil 34D) during the monitoring operation of the driving circuit DRC by the function of the inductance estimating part 8013.

When the processing of the step S308 is completed, the door control device 80 proceeds to a step S310.

In the step S310, the monitoring part 801 of the door control device 80 estimates the protrusion A of the plunger 34B during the monitoring operation of the driving circuit DRC by the function of the protrusion estimating part 8014.

When the processing of the step S310 is completed, the door control device 80 proceeds to a step S312.

In the step S312, the monitoring part 801 of the door control device 80 determines whether or not the estimated value of the protrusion A of the plunger 34B during the monitoring operation of the driving circuit DRC is equal to or greater than the threshold Ath3 by the function of the determining part 8015. When the estimated value of the protrusion A of the plunger 34B is equal to or greater than the threshold Ath3, the monitoring part proceeds to step a S314, and when it is not equal to or greater than the threshold Ath3, the monitoring part 801 proceeds to a step S316.

In the step S314, the monitoring part 801 of the door control device 80 determines that the door 10 is normally unlocked by the locking device 30 (i.e., “Unlock: OK”) by the function of the determining part 8015.

Conversely, in the step S316, the monitoring part 801 of the door control device 80 determines, by the function of the determining part 8015, that the door 10 is not normally unlocked by the locking device 30 (i.e., “Unlock: NG”).

When the processing of the step S314 or the step S316 is completed, the door control device 80 proceeds to a step S318.

In the step S318, by the function of the determining part 8015, the monitoring part 801 of the door control device 80 outputs a flag indicating the determination result of whether or not the door 10 is normally unlocked by the locking device 30 to the outside.

When the processing of the step S318 is completed, the door control device 80 completes the process of the present flowchart.

### Fourth Example of Locking Device State Monitoring Method

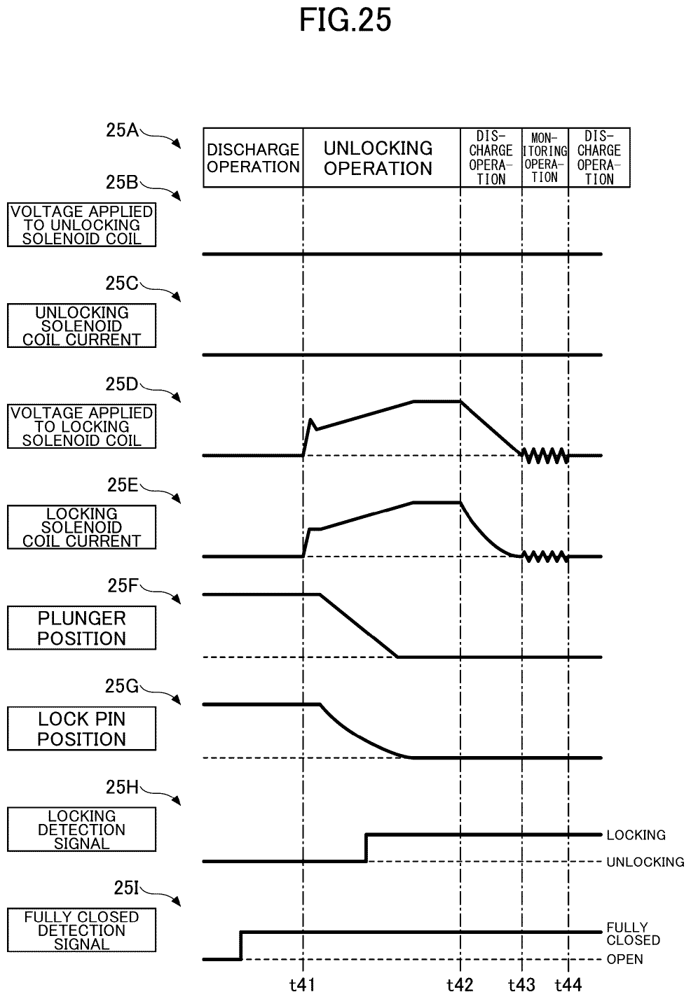

Next, with reference to FIG. 25, a fourth example of monitoring the state of the locking device 30 by the door control device 80 will be described.

In this example, a description is performed based on the configuration of the locking device 30 shown in FIG. 19 and FIG. 20, and the driving circuit DRC shown in FIG. 21, similar to the third example of the monitoring method described above. Moreover, the configuration of the state monitoring function of the locking device 30 may be the same as in the first example (FIG. 6) described above. Therefore, in this example, FIG. 6 is used and illustration of a functional block diagram showing the configuration according to this example is omitted. In addition, in this example, the description will be focused on the parts different from the first to third examples of the monitoring method described above, and the same or corresponding parts as the first to third examples of the monitoring method described above may be omitted.

FIG. 25 is a time chart describing a fourth example of a method for monitoring the state of the locking device 30.

Specifically, FIG. 25 includes Portions 25A to 25I. Portion 25A is a time chart showing the flow of the operation of the driving circuit DRC when the door 10 is locked by the locking device 30. Portions 25B to 25I are time charts showing an example of locking operation of the locking device 30 when the locking device 30 is in a normal state. Portion 25B is a time chart showing time variation of applied voltage of the unlocking solenoid coil (coil 34C) when the locking device 30 locks the door 10. Portion 25C is a time chart showing time variation of current of the unlocking solenoid coil (coil 34C) when the locking device 30 locks the door 10. Portion 25D is a time chart showing time variation of applied voltage of the locking solenoid coil (coil 34D) when the locking device 30 locks the door 10. Portion 25E is a time chart showing time variation of current of the locking solenoid coil (coil 34D) when the locking device 30 locks the door 10. Portion 25F is a time chart showing time variation of the vertical position of the plunger 34B when the locking device 30 locks the door 10. Portion 25G is a time chart showing time variation of the vertical position of the lock pin 31 when the locking device 30 locks the door 10. Portion 25H is a time chart showing time variation of the locking detection signal when the locking device 30 locks the door 10. Portion 25I is a time chart showing time variation of the fully closed detection signal when the locking device 30 locks the door 10.

As shown in Portion 25I, when the door 10 reaches the fully closed position due to the closing operation of the door 10, the fully closed detection signal is switched from the off signal to the on signal. Thus, the control circuit 82 can determine that the lock pin 31 has shifted to the state in which it can be inserted into the lock hole 32A. Therefore, at a subsequent time t41, the driving circuit DRC shifts from the discharge operation state to the locking operation controlled by the control circuit 82.

As shown in Portions 25D and 25E, in the locking operation of the driving circuit DRC, a direct voltage of a predetermined pattern is applied to the locking solenoid coil (coil 34D) controlled by the control circuit 82. Then, a direct current of a predetermined pattern is applied to the coil 34D by the current feedback control by the control circuit 82. Consequently, as shown in Portion 25F, after the time t41, the plunger 34B starts moving downward, and in accordance with this, the lock pin 31 starts moving downward, as shown in Portion 5E of FIG. 5. Then, as shown in Portion 25H, as the plunger 34B moves downward, the vertical slider 35 comes into contact with and presses the actuator part 52 of the locking detection switch 50, thereby switching the locking detection signal from ON to OFF.

As shown in Portion 25F, the plunger 34B continues moving downward by energizing the coil 34D, and reaches its lower limit position. As shown in Portion 25G, the lock pin 31 continues to move downward by the self-weight in accordance with the downward movement of the plunger 34B, and reaches its own lower limit position immediately after the plunger 34B reaches its lower limit position. Thus, the locking device 30 can achieve the fully locked state of the door 10.

After the lock pin 31 reaches its lower limit position, the driving circuit DRC shifts from the locking operation to the discharge operation controlled by the control circuit 82 at a time t42.

As shown in Portions 25D and 25E, in the discharge operation state of the driving circuit DRC after the time t42, the applied voltage and current of the coil 34D decrease toward zero. Subsequently, when the applied voltage and current of the coil 34D converge to zero, the driving circuit DRC shifts from the discharge operation state to the operation for monitoring the state of the locking device 30 (monitoring operation) controlled by the control circuit 82 at a time t43.

As shown in Portions 22D and 22F of FIG. 22, in the monitoring operation of the driving circuit DRC, controlled by the control circuit 82, an alternating voltage of a predetermined amplitude and a predetermined frequency with the zero reference of voltage is applied to the locking solenoid coil (coil 34D), and an alternating current flows to the coil 34D. At this time, since the DIRECT CURRENT component of the alternating voltage applied to the coil 34D is zero, the position of the plunger 34B does not change as shown in Portion 25F.

As shown in Portion 25A, when the monitoring operation is completed, the driving circuit DRC shifts to the discharge operation at a time t44.

For example, the door control device 80 executes the monitoring operation according to this example in accordance with the closing operation of the door 10 and the locking operation of the locking device 30 during the actual operation of the railway vehicle 1. Thus, for example, the door control device 80 can monitor the state of the locking device 30 in real time during the actual operation of the railway vehicle 1. In addition, the door control device 80 may execute the monitoring operation according to this example in accordance with the closing operation of the door 10 and the locking operation of the locking device 30 during the inspection of the railway vehicle 1 in the rail yard or the like.

For example, as shown in FIG. 6, the door control device 80 includes a monitoring part 801 as a function part for monitoring the state of the locking device 30 as in the first and third examples described above. Hereinafter, in this example, the description will focus on the different parts from the first example (FIG. 6) described above, and the same or corresponding parts may be omitted.

The monitoring part 801 includes a current amplitude detecting part 8011, a mean current calculating part 8012, an inductance estimating part 8013, a protrusion estimating part 8014, and a determining part 8015, as in the first and third examples described above.

The current amplitude detecting part 8011 detects the current amplitude ΔIₛ of the coil 34D during the monitoring operation of the driving circuit DRC, as in the third example described above.

The mean current calculating part 8012 calculates the average value (mean current I_{s_mean}) Of the current Iₛ of the coil 34D during the monitoring operation of the driving circuit DRC, as in the third example described above.

The inductance estimating part 8013 estimates the inductance L of the coil 34D during the monitoring operation of the driving circuit DRC, as in the third example described above.

The protrusion estimating part 8014 estimates the protrusion A of the plunger 34B during the monitoring operation of the driving circuit DRC, as in the third example described above.

The determining part 8015 determines the locking state of the door 10 by the locking device 30 based on the estimated value of the protrusion A of the plunger 34B output from the protrusion estimating part 8014.

For example, the determining part 8015 determines whether or not the estimated value of the protrusion A of the plunger 34B during the monitoring operation of the driving circuit DRC is smaller than the threshold Ath4. The threshold Ath4 is a positive value (Ath4>0) and is set in advance as a value between the maximum value Amax and the minimum value Amin of the protrusion A of the plunger 34B (specifically, 0<Amin<Ath4<Amax).

For example, the threshold Ath4 is set as the upper limit value of the protrusion A of the plunger 34B to achieve the state in which the lock pin 31 is inserted into the lock hole 32A and the locking detection signal is the ON signal, similar to the threshold Ath2 of the second example described above. Specifically, the threshold Ath4 is set to the sum (addition value) of the initial value of the protrusion of the plunger 34B, the gap between the plunger 34B and the vertical slider 35, and the vertical difference between the lower limit position of the lock pin 31 and the position at which the locking detection signal is switched to the ON signal. Thus, when the protrusion A of the plunger 34B during the monitoring operation of the driving circuit DRC is equal to or greater than the threshold Ath4, the determining part 8015 can determine that the locking of the door 10 has not been completed normally due to the sticking of the plunger 34B or the like. Conversely, when the protrusion A of the plunger 34B during the monitoring operation of the driving circuit DRC is smaller than the threshold Ath4, the determining part 8015 can determine that there is no abnormality in the position of the plunger 34B due to the sticking or the like.

The determining part 8015 outputs to the outside a flag indicating the determination result, that is, an OK flag indicating that the position of the plunger 34B is normal, or an NG flag indicating that the locking of the door 10 has not been completed normally due to an abnormality in the position of the plunger 34B.

Thus, in this example, after the locking operation of the driving circuit DRC is completed, the door control device 80 causes the driving circuit DRC to execute a monitoring operation for applying an alternating voltage to the coil 34D. Then, the door control device 80 estimates the inductance of the coil 34D based on the voltage and current of the coil 34D during the monitoring operation, so that it is possible to monitor a state in which the door 10 is not locked normally due to the position of the plunger 34B.

### Fourth Example of Control Processing of Door Control Device

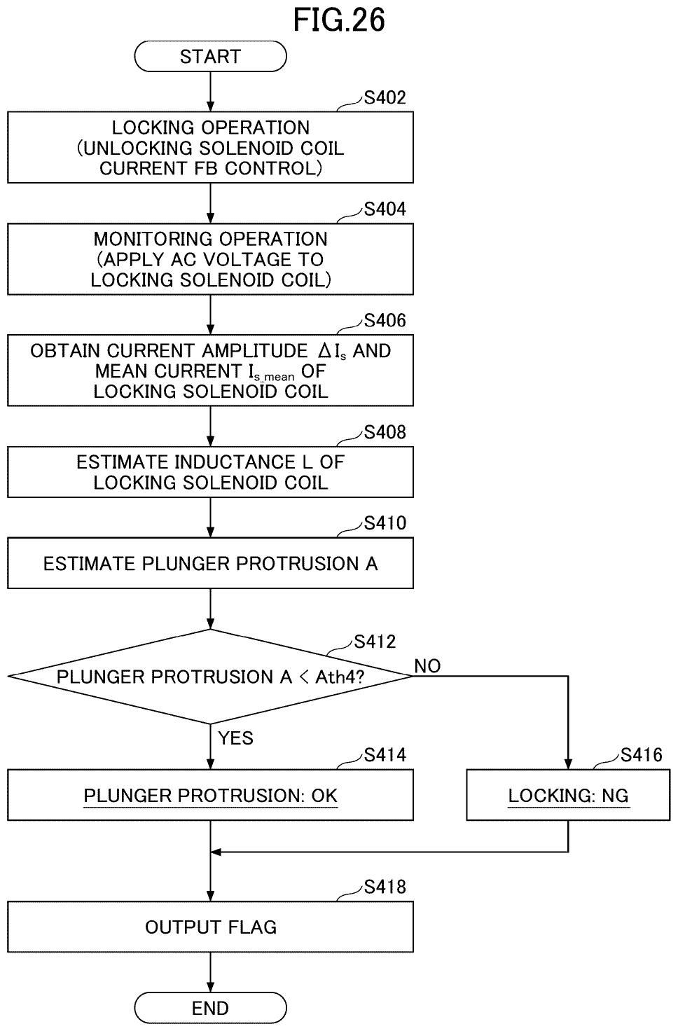

Next, a fourth example of control processing of the door control device 80 will be described with reference to FIG. 26. Specifically, a specific example of control processing of the door control device 80 including a processing flow corresponding to the fourth example of the monitoring method of the state of the locking device 30 will be described.

FIG. 26 a flowchart schematically is illustrating the fourth example of control processing of the door control device 80.

This flowchart is disclosed, for example, when a command from the host device instructing the opening operation of the door 10 is input to the door control device 80 and the fully closed detection signal is switched from the OFF signal to the ON signal.

As shown in FIG. 26, in a step S402, the control circuit 82 of the door control device 80 controls the inverter circuit 83 to cause the driving circuit DRC to execute the locking operation. At this time, the control circuit 82 performs current feedback control of the locking solenoid coil (coil according to a predetermined current pattern 34D) based on the output of the current sensor 70.

When the processing of the step S402 is completed, the door control device 80 proceeds to a step S404.

In the step S404, the control circuit 82 of the door control device 80 controls the inverter circuit 83 to cause the driving circuit DRC to execute the monitoring operation. At this time, the control circuit 82 applies an alternating voltage to the locking solenoid coil (coil 34D) by the driving circuit DRC as described above.

When the processing of the step S404 is completed, the door control device 80 proceeds to a step S406.

In the step S406, the monitoring part 801 of the door control device 80 obtains the current amplitude ΔIₛ and the mean current I_{s_mean} of the locking solenoid coil (coil 34D) during the monitoring operation by the functions of the current amplitude detecting part 8011 and the mean current calculating part 8012.

When the processing of the step S406 is completed, the door control device 80 proceeds to a step S408.

In the step S408, the monitoring part 801 of the door control device 80 estimates the inductance L of the locking solenoid coil (coil 34D) during the monitoring operation of the driving circuit DRC by the function of the inductance estimating part 8013.

When the processing of the step S408 is completed, the door control device 80 proceeds to a step S410.

In the step S410, the monitoring part 801 of the door control device 80 estimates the protrusion A of the plunger 34B during the monitoring operation of the driving circuit DRC by the function of the protrusion estimating part 8014.

When the processing of the step S410 is completed, the door control device 80 proceeds to a step S412.

In the step S412, the monitoring part 801 of the door control device 80 determines whether or not the estimated value of the protrusion A of the plunger 34B during the monitoring operation of the driving circuit DRC is smaller than the threshold Ath4 by the function of the determining part 8015. When the estimated value of the protrusion A of the plunger 34B is smaller than the threshold Ath4, the monitoring part proceeds to a step S414, and when it is not equal to or greater than the threshold Ath3, the monitoring part 801 proceeds to a step S416.

In the step S414, the monitoring part 801 of the door control device 80 determines, by the function of the determining part 8015, that the amount of protrusion of the plunger 34B during the locking operation of the door 10 by the locking device 30 is normal (i.e., “Plunger protrusion: OK”).

Conversely, in the step S416, the monitoring part 801 of the door control device 80 determines, by the function of the determining part 8015, that the door 10 is not normally locked by the locking device 30 (i.e., “Locking: NG”).

When the processing of the step S414 or step S416 is completed, the door control device 80 proceeds to a step S418.

In the step S418, by the function of the determining part 8015, the monitoring part 801 of the door control device 80 outputs a flag indicating the determination result of the step S416 or the step S146 to the outside.

When the processing of the step S418 is completed, the door control device 80 completes the process of the present flowchart.

### Third Example of Locking Device

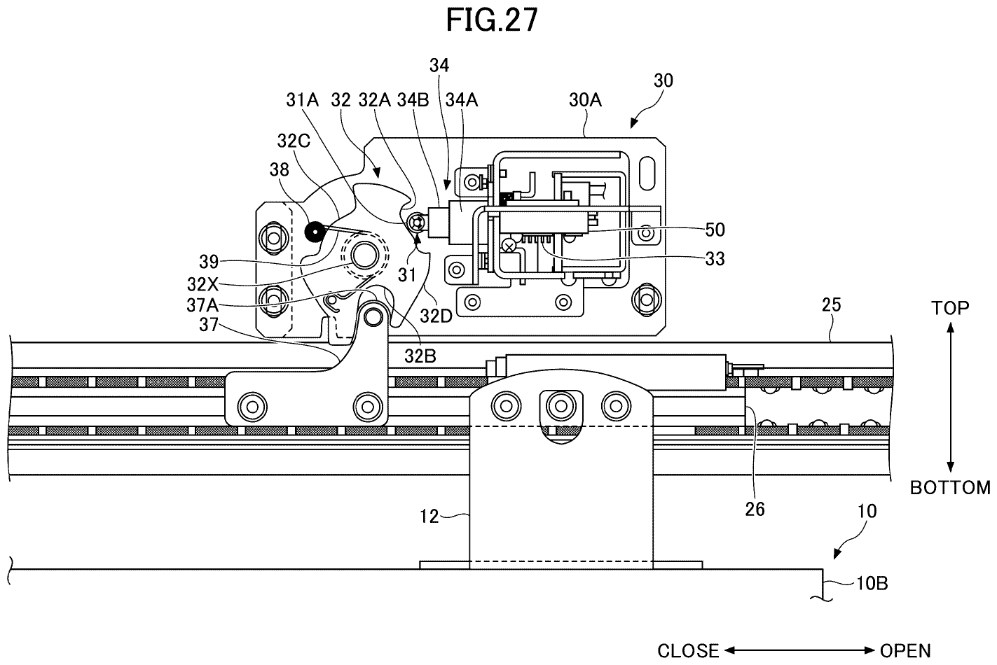

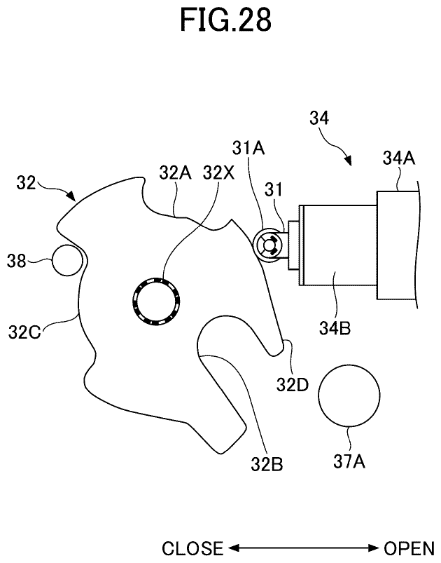

Next, a third example of the locking device 30 according to the present embodiment will be described with reference to FIGS. 27 and 28.

Hereinafter, in this example, the same or corresponding components of the locking device 30 as those of the first and second examples are denoted by the same reference numerals, and the description will be given mainly on the parts different from those of the first and second examples, and the description of the same or corresponding parts of the first and second examples may be omitted.

FIGS. 27 and 28 are drawings illustrating the third example of the locking device 30 of the door 10.

Specifically, FIG. 27 is a drawing illustrating the third example of the locking device 30 when the door 10 is in the fully closed position and the door 10 is in the locked state close to the locking device 30. FIG. 28 is a drawing illustrating a third example of the locking device 30 when the door 10 is in the open state and the door 10 is in the unlocked state by the locking device 30.

FIG. 27 shows only the door panel 10B of the door panels 10A and 10B included in the door 10. FIG. 28 does not show the door 10 or the like. In this example, the driving circuit DRC of the locking device 30 may have the same configuration as that of the first example (FIGS. 2 and 3), that is, the same configuration as that of FIG. 4. Therefore, in this example, FIG. 4 is used and illustration of the driving circuit DRC according to this example is omitted.

As shown in FIGS. 27 and 28, in this example, the door driving mechanism 20 includes a rail 25 and a slider 26.

The rail 25 is arranged so as to extend in the longitudinal direction above the door opening of the vehicle body of the railway vehicle 1.

The slider 26 is held by the rail 25. The slider 26 can be moved along the rail 25 by the power of an electric motor (not shown).

The door panel 10B is connected to the slider 26 by a connecting member 12. Thus, the door 10 can open and close along the rail 25.

The locking device 30 includes a lock pin 31, an opening and closing interlocking member 32, a biasing spring 33, a solenoid 34, a driving member 37, a regulating member 38, and a torsion spring 39.

The lock pin 31 is a member corresponding to the tip of the plunger 34B of the solenoid 34. The lock pin 31 is movable in the longitudinal direction of the railway vehicle 1 by the movement of the plunger 34B. A roller 31A is provided at the tip of the lock pin 31. Thus, as will be described later, when the lock pin 31 abuts against the outer peripheral surface (abutting surface 32D) of the opening and closing interlocking member 32, the roller 31A rotates, so that the lock pin 31 can smoothly keep abutting against the outer peripheral surface even when the opening and closing interlocking member 32 rotates.

The opening and closing interlocking member 32 is a cam member which is attached to a mounting plate 30A attached to the vehicle body of the railway vehicle 1 via a rotating shaft 32X and rotatable about a rotating shaft 32X having an axial center along the width direction of the railway vehicle 1. The outer peripheral surface of the opening and closing interlocking member 32 is provided with a lock hole 32A, recesses 32B and 32C, and an abutting surface 32D.

The lock hole 32A is a recess provided so that the lock pin 31 can be inserted. The opening and closing interlocking member 32 can rotate within a predetermined angle range when the lock pin 31 is not inserted into the lock hole 32A, while its rotation is restricted when the lock pin 31 is inserted into the lock hole 32A.

The recess 32B is provided so that the projection 37A of the driving member 37 can be inserted.

The recess 32C is formed in a predetermined circumferential range of the outer peripheral surface, and the regulating member 38 is arranged in the recess 32C.

The abutting surface 32D is a portion where the lock pin 31 abuts when the door 10 is in the open state among the outer peripheral surfaces excluding the portions where the lock hole 32A and the recesses 32B and 32C are provided.

The biasing spring 33 biases the plunger 34B toward the opening and closing interlocking member 32.

The solenoid 34 is an actuator for moving the lock pin 31 away from the opening and closing interlocking member 32. As in the first example described above, the solenoid 34 includes the housing 34A, the plunger 34B, and the coil 34C (see FIG. 4).

As described above, the plunger 34B is biased toward the opening and closing interlocking member 32 by the biasing spring 33, and when the coil 34C is not energized, the plunger protrudes from the the housing 34A toward opening and closing interlocking member 32. Conversely, when the coil 34C is energized, the plunger 34B is attracted to the magnetized fixed iron core inside the housing 34A and moves away from the opening and closing interlocking member 32, thereby shifting to a state where most of the plunger 34B is accommodated in the housing 34A.

The driving member 37 is connected to the slider 26 and moves in the opening and closing direction of the door 10 in association with the opening and closing operation of the door 10. The driving member 37 has a projection 37A.

The projection 37A is inserted into the recess 32B of the opening and closing interlocking member 32 when the door 10 is relatively close to the fully closed position.

The regulating member 38 is provided in the mounting plate 30A so as to be disposed in the recess 32C. The regulating member 38 can limit the rotatable range of the opening and closing interlocking member 32 to a predetermined angular by abutting against both circumferential ends of the recess 32C.

The torsion spring 39 energizes the opening and closing interlocking member 32 so that its posture around the rotating shaft 32X returns to a predetermined reference state. Specifically, the reference state is the posture state of the opening and closing interlocking member 32 shown in FIG. 28, and the posture state in which the lock pin 31 abuts against the abutting surface 32D.

For example, when the door 10 is closed, the driving member 37 moves from the state shown in FIG. 28 to the left, and the projection 37A is inserted into the recess 32B. As a result, the opening and closing interlocking member 32 rotates clockwise in the figure as the driving member 37 moves in the closing direction (i.e., to the left in the figure) according to the closing operation of the door 10. As shown in FIG. 27, when the door 10 reaches the fully closed position, the lock pin 31 shifts from the state of abutting against the abutting surface 32D to the state of being inserted into the lock hole 32A due to the biasing force of the biasing spring 33 acting on the plunger 34B, and the rotation of the opening and closing interlocking member 32 is regulated. Therefore, the locking device 30 can shift the door 10 from the unlocked state to the locked state by inserting the lock pin 31 into the lock hole 32A of the opening and closing interlocking member 32 according to the closing operation of the door 10.

In addition, when the door 10 opens, the coil 34C of the solenoid 34 is energized, and the plunger 34B is pulled into the direction of the housing 34A (i.e., in the right direction in the figure). Thus, the state of restricting the rotation of the opening and closing interlocking member 32 is released, and the driving member 37 having the projection 37A can move in the opening direction of the door 10 (i.e., in the right direction in the figure) while rotating the opening and closing interlocking member 32. Therefore, when the opening operation of the door 10 starts, the locking device 30 can shift the door 10 from the locked state to the unlocked state by energizing the coil 34C and moving the plunger 34B away from the opening and closing interlocking member 32 (toward the right in the figure).

The locking detection switch 50 is arranged so as to be adjacent to the solenoid 34 in the width direction of the railway vehicle 1. In this example, the locking detection switch 50 is switched ON or OFF by mechanical action from the plunger 34B at a position where the lock pin 31 is inserted into the lock hole 32A to some extent in the radial direction about the rotating shaft 32X.

### Fifth Example of Locking Device State Monitoring Method

Next, a fifth example of monitoring the state of the locking device 30 by the door control device 80 will be described.

Hereinafter, in this example, a description is performed based on the configuration of the locking device 30 shown in FIG. 27 and FIG. 28, and the driving circuit DRC shown in FIG. 4. Moreover, the configuration of the state monitoring function of the locking device 30 may be the same as in the first example (FIG. 6) described above. Therefore, in this example, FIG. 6 is used and the functional block diagram showing the configuration thereof is omitted.

In addition, in this example, the description will be focused on the parts different from the first to fourth examples of the monitoring method described above, and the same or corresponding parts as the first to fourth examples of the monitoring method described above may be omitted.

In this example, the door control device 80 monitors the unlocking state of the door 10 by a method similar to the first example of the monitoring method described above.

Specifically, as in the first example of the monitoring method described above, the door control device 80 causes the driving circuit DRC to execute an unlocking operation when the door 10 is unlocked. As a result, DIRECT CURRENT is applied to the coil 34C of the solenoid 34, the plunger 34B is moved away from the opening and closing interlocking member 32, and the state in which the lock pin 31 at the tip of the plunger 34B is inserted into the lock hole 32A can be released.

As in the first example of the monitoring method described above, the door control device 80 causes the driving circuit DRC to execute a monitoring operation after the unlocking operation of the driving circuit DRC is completed. In the monitoring operation of the driving circuit DRC, an alternating voltage based on a certain voltage is applied to the coil 34C as in the first example of the monitoring method described above.

For example, the door control device 80 executes the unlocking operation and the monitoring operation according to this example in accordance with the opening operation of the door 10 during the actual operation of the railway vehicle 1. Thus, for example, the door control device 80 can monitor the state of the locking device 30 in real time during the actual operation of the railway vehicle 1. In addition, the door control device 80 may execute the unlocking operation and the monitoring operation according to this example in accordance with the opening operation of the door 10 during the inspection of the railway vehicle 1 at the rail yard or the like.

As shown in FIG. 6, the door control device 80 includes a monitoring part 801 as a function part for monitoring the state of the locking device 30, as in the first to fourth examples of the monitoring method described above.

As in the first to fourth examples of the monitoring method described above, the monitoring part 801 includes a current amplitude detecting part 8011, a mean current calculating part 8012, an inductance estimating part 8013, a protrusion estimating part 8014, and a determining part 8015.

The protrusion estimating part 8014 estimates the protrusion A of the plunger 34B during the monitoring operation of the driving circuit DRC, as in Example 1 of the monitoring method described above. In this example, the protrusion of the plunger 34B means the protrusion of the plunger 34B from the housing 34A toward the opening and closing interlocking member 32, and the same applies to Example 6 of the monitoring method described below.

For example, as in the first example of the monitoring method described above, the protrusion estimating part 8014 estimates the protrusion A of the plunger 34B from the estimated value of the inductance L of the coil 34C using the correlation information.

As in the first example of the monitoring method described above, the determining part 8015 determines the unlocking state of the door 10 by the locking device 30 based on the estimated value of the protrusion A of the plunger 34B during the monitoring operation of the driving circuit DRC estimated by the protrusion estimating part 8014.

For example, the determining part 8015 determines whether the protrusion A of the plunger 34B is less than or equal to the threshold Ath5. The threshold Ath5 is a positive value (Ath5>0) and is set in advance as a value between the maximum value Amax and the minimum value Amin of the protrusion A of the plunger 34B (specifically, 0≤Amin<Ath5<Amax).

For example, the threshold Ath5 is set as an upper limit value of the protrusion A of the plunger 34B to achieve the state in which the lock pin 31 is not inserted into the lock hole 32A. Specifically, the threshold Ath5 is set as a value obtained by subtracting the lap amount between the lock pin 31 and the lock hole 32A in the radial direction around the rotating shaft 32X when the protrusion of the plunger 34B is the maximum value from the maximum value of the protrusion A of the plunger 34B. Thus, when the estimated value of the protrusion A of the plunger 34B is less than or equal to the threshold Ath5, the determining part 8015 can determine that the tip of the lock pin 31 is at a position equal to or more distant from the opening of the lock hole 32A in the radial direction with the rotating shaft 32X as a reference. Therefore, when the estimated value of the protrusion A of the plunger 34B is less than or equal to the threshold Ath5, the determining part 8015 can determine that the door 10 is normally unlocked. Conversely, when the estimated value of the protrusion A of the plunger 34B is greater than the threshold Ath5, the determining part 8015 can determine that the door 10 is not normally unlocked by the locking device 30.

As in the first example of the monitoring method described above, the determining part 8015 outputs to the outside a flag representing the determination result, that is, a locking OK flag representing that the door 10 is normally unlocked, or a locking NG flag representing that the door 10 is not normally unlocked.

Thus, in this example, as in the first example of the monitoring method described above, after the unlocking operation of the driving circuit DRC is completed, the door control device 80 causes the driving circuit DRC to execute a monitoring operation for applying an alternating voltage to the coil 34C. Then, the door control device 80 can monitor whether the door 10 is normally unlocked by estimating the inductance of the coil 34C based on the voltage and current of the coil 34C during the monitoring operation of the driving circuit DRC.

### Sixth Example of Locking Device State Monitoring Method

Next, a sixth example of monitoring the state of the locking device 30 by the door control device 80 will be described.

Hereinafter, in this example, a description is performed based on the configuration of the locking device 30 shown in FIG. 27 and FIG. 28, and the driving circuit DRC shown in FIG. 4. Moreover, the configuration of the state monitoring function of the locking device 30 may be the same as in the first example (FIG. 6) described above. Therefore, in this example, FIG. 6 is used and the illustration of the functional block diagram showing the configuration of this example is omitted. In addition, in this example, the description will be focused on the parts different from the first to fifth examples of the monitoring method described above, and the same or corresponding parts as in the first to fifth examples of the monitoring method described above may be omitted.

In this example, the door control device 80 monitors the unlocking state of the door 10 by a method similar to the second example of the monitoring method described above.

In this example, as in the second example of the monitoring method described above, the door control device 80 causes the driving circuit DRC to execute the monitoring operation after the locking operation of the locking device 30 is completed when the door 10 is closed.

In this example, unlike the second example of the monitoring method described above, the monitoring operation of the driving circuit DRC includes only the operation mode 1 of the operation modes 1 to 3 described above. That is, in this example, controlled by the control circuit 82, the driving circuit DRC applies an alternating voltage of a predetermined amplitude and a predetermined frequency with the zero reference of voltage to the coil 34C in the monitoring operation. At this time, as in the operation mode 1 of the second example of the monitoring method described above, the plunger 34B does not move and the position of the lock pin 31 does not change.

For example, the door control device 80 executes the monitoring operation according to this example in accordance with the closing operation of the door 10 and the locking operation of the locking device 30 during the actual operation of the railway vehicle 1. Thus, for example, the door control device 80 can monitor the state of the locking device 30 in real time during the actual operation of the railway vehicle 1. In addition, the door control device 80 may execute the monitoring operation according to this example in accordance with the closing operation of the door 10 and the locking operation of the locking device 30 during the inspection of the railway vehicle 1 in the rail yard or the like.

As shown in FIG. 6, the door control device 80 includes a monitoring part 801 as a function part for monitoring the state of the locking device 30, as in the first to fifth examples of the monitoring method described above.

As in the first to fifth examples of the monitoring method described above, the monitoring part 801 includes a current amplitude detecting part 8011, a mean current calculating part 8012, an inductance estimating part 8013, a protrusion estimating part 8014, and a determining part 8015.

The protrusion estimating part 8014 estimates the protrusion A of the plunger 34B during the monitoring operation of the driving circuit DRC.

For example, as in the first to fifth examples of the monitoring method described above, the protrusion estimating part 8014 estimates the protrusion A of the plunger 34B from the estimated value of the inductance L of the coil 34C using the correlation information.

Based on the estimated value of the protrusion A of the plunger 34B during the monitoring operation of the driving circuit DRC estimated by the protrusion estimating part 8014, the determining part 8015 determines the unlocking state of the door 10 by the locking device 30.

For example, the determining part 8015 determines whether or not the protrusion A of the plunger 34B is greater than the threshold Ath6. The threshold Ath6 is a positive value (Ath6>0) and is preset as a value between the maximum value Amax and the minimum value Amin of the protrusion A of the plunger 34B (specifically, 0≤Amin<Ath6<Amax).

For example, the threshold Ath6 is set as a lower limit value of the plunger 34B protrusion A to achieve a state in which the lock pin 31 is inserted into the lock hole 32A and the locking detection signal is an ON signal. Specifically, the threshold Ath6 is set to the protrusion of the plunger 34B when the locking detection signal is switched to an ON signal. This is because the locking detection signal is switched to an ON signal when the lock pin 31 is inserted into the lock hole 32A to some extent from the viewpoint of safety. Thus, when the estimated value of the plunger 34B protrusion A during the monitoring operation of the driving circuit DRC is less than or equal to the threshold Ath6, the determining part 8015 can determine that the door 10 is not normally locked due to the sticking of the plunger 34B. Conversely, when the estimated value of the plunger 34B protrusion A during the monitoring operation of the driving circuit DRC is greater than the threshold Ath6, the determining part 8015 can determine that there is no abnormality in the position of the plunger 34B due to sticking, and that the door 10 is normally locked.

As in the first to third and fifth examples of the monitoring method described above, the determining part 8015 outputs to the outside a flag indicating the determination result, that is, the locking OK flag indicating that the door 10 is normally unlocked or the locking NG flag indicating that the door 10 is not normally unlocked.

Thus, in this example, as in the first to fifth examples of the monitoring method described above, after the unlocking operation of the driving circuit DRC is completed, the door control device 80 causes the driving circuit DRC to execute the monitoring operation for applying an alternating voltage to the coil 34C. The door control device 80 can monitor whether or not the door 10 is normally locked by estimating the inductance of the coil 34C based on the voltage and current of the coil 34C during the monitoring operation of the driving circuit DRC.

### Other Examples of Locking Devices

Next, other examples of the locking device 30 will be described.

The first to third examples of the locking devices described above may be modified or changed as appropriate.

For example, in the first and second examples of the locking device 30 described above, the upper end of the plunger 34B may be connected to the lower surface of the vertical slider 35.

In this case, in the first example of the monitoring method described above, for example, the threshold value Ath1 is set as the sum (addition value) of the initial value of the protrusion of the plunger 34B and the vertical lap amount between the lock pin 31 and the lock hole 32A in the locked state of the door 10. This is because there is no gap between the plunger 34B and the vertical slider 35. Similarly, in this case, in the second example of the monitoring method described above, the threshold Ath2 is set to, for example, the sum (addition value) of the initial value of the plunger 34B protrusion and the vertical difference between the lower limit position of the lock pin 31 and the position at which the locking detection signal is switched to the ON signal. Similarly, in this case, in the third example of the monitoring method described above, the threshold Ath3 is set to, for example, the sum (addition value) of the initial value of the plunger 34B protrusion and the vertical lap amount between the lock pin 31 and the lock hole 32A in the locked state of the door 10. Similarly, in this case, in the fourth example of the monitoring method described above, the threshold Ath4 is set to the sum (addition value) of the initial value of the plunger 34B protrusion and the vertical difference between the lower limit position of the lock pin 31 and the position at which the locking detection signal is switched to the ON signal. In this case, in the second example of the monitoring method, the door control device 80 causes the driving circuit DRC to execute only the operation mode 1 as the monitoring operation, and omits execution of the operation modes 2 and 3. This is because when the tip of the plunger 34B and the vertical slider 35 are connected, t can be determined that the position of the lock pin 31 interlocking with the vertical slider 35 is also normal because the position of the plunger 34B is normal. In this case, in the fourth example of the monitoring method, the monitoring part 801 of the door control device 80 may determine that the door 10 is normally locked when the estimated value of the protrusion A of the plunger 34B is smaller than the threshold Ath4. This is because when the tip of the plunger 34B and the vertical slider 35 are connected, it can be determined that the position of the lock pin 31 interlocking with the vertical slider 35 is also normal because the position of the plunger 34B is normal.

In the third example of the locking device 30 described above, the solenoid 34 may be a self-holding type as in the second example described above. In this case, the solenoid 34 includes, in addition to the coil 34C for moving the plunger 34B away from the opening and closing interlocking member 32, a coil 34D for moving the plunger 34B toward the opening and closing interlocking member 32, and the biasing spring 33 may be omitted.

### Other Examples of Locking Device State Monitoring Method

Next, other examples of monitoring the state of the locking device 30 will be described.

The first to sixth examples of the monitoring methods of the state of the locking device 30 may be modified or changed as appropriate.

For example, in the second example of the monitoring method described above, the monitoring part 801 of the door control device 80 may determine whether or not the door 10 is normally locked based only on the first and second determination conditions among the first to third determination conditions described above. This is because it is possible to determine that the door 10 is normally locked when the locking detection signal is switched on. In this case, the control circuit 82 of the door control device 80 may cause the driving circuit DRC to execute only the operation modes 1 and 2 of the operation modes 1 to 3 as the monitoring operation, and may omit the operation mode 3.

In the second example of the monitoring method described above, the monitoring part 801 of the door control device 80 may determine whether or not the door 10 is normally locked by only the first and third determination conditions among the first and third determination conditions described above. This is because the monitoring part 801 of the door control device 80 can determine whether or not the position of the lock pin 31 is normal from the estimated value of the protrusion A of the plunger 34B during the execution of the operation mode 3 of the driving circuit DRC. In this case, the control circuit 82 of the door control device 80 may cause the driving circuit DRC to execute only the operation modes 1 and 3 of the operation modes 1 to 3 as the monitoring operation, and may omit the execution of the operation mode 2.

In the third example of the monitoring method described above, the control circuit 82 of the door control device 80 may apply an alternating voltage with the zero reference of voltage to the coil 34C instead of or in addition to the coil 34D during the monitoring operation of the driving circuit DRC. In this case, the monitoring part 801 of the door control device 80 estimates, for example, the inductance L of the coil 34C, and estimates the protrusion of the plunger 34B based on the estimated value.

In addition, the door control device 80 may execute either one or both of the first and second examples of the monitoring method described above on the assumption of the first example of the locking device 30 and the examples of modification and change thereof. In the latter case, the configuration shown in FIG. 10 described above is adopted for the monitoring part 801 of the door control device 80.

In addition, the door control device 80 may execute either one or both of the third and fourth examples of the monitoring method on the premise of the second example of the locking device 30 and examples of modification and change thereof.

In addition, the door control device 80 may execute either one or both of the fifth and sixth examples of the monitoring method on the premise of the third example of the locking device 30 and examples of modification and change thereof.

In addition, the door control device 80 may monitor a state of the locking device 30 different from the locking or unlocking state of the door 10 by the locking device 30 by energizing the coils 34C and 34D of the solenoid 34. For example, the door control device 80 monitors the deterioration state and the life of the locking device 30 based on the monitoring result of the locking or unlocking state of the door 10 and the accumulated log of the associated information as described above. In addition, the door control device 80 may monitor whether or not the plunger 34B moves normally by energizing the coils 34C and 34D with direct voltage and checking whether or not the current decreases due to the back electromotive force, regardless of the unlocking or locking operation of the locking device 30. In addition, under the assumption that the plunger 34B is normal, the door control device 80 may monitor whether or not the vertical slider 35 and the lock pin 31 move normally by the same method. In addition, the door control device 80 may estimate the movement amount of the plunger 34B by applying alternating voltage to the coils 34C and 34D, regardless of the unlocking or locking operation of the locking device 30, and monitor whether or not the movement amount is appropriate, or may estimate the deterioration state from the movement amount.

### Other Embodiments

Next, other embodiments will be described.

The above-described embodiments may be modified or modified as appropriate.

For example, in the above-described embodiment, instead of providing a monitoring reference (e.g., threshold) for the protrusion A of the plunger 34B, the door control device 80 may directly provide a monitoring reference for the inductance L of the coil 34C and monitor the state of the locking device 30.

In the above-described embodiment and the examples of modifications and variations, the lock pin 31 is provided toward the vehicle body (i.e., the fixed part) of the railway vehicle 1, and the lock hole 32A is provided toward the door 10 (i.e., the moving part) interlocked with the opening and closing operation of the door 10.

In addition, in the above-described embodiments and examples of modifications and changes, in place of or in addition to the door control device 80, monitoring of the same state of the locking device 30 as described above may be performed by an upper device of the railway vehicle 1 or an external device of the railway vehicle 1.

### [Action]

Next, the action of the monitoring device, the monitoring method, and the program according to the present embodiment will be described.

According to a first aspect of the present embodiment, a monitoring device for monitoring a state of a locking device, the locking device includes a first member, a second member configured to achieve a locked state of a door of a railway vehicle by establishing a predetermined positional relation with the first member upon a movement toward the first member, and a solenoid configured to move the second member in a first direction away from the first member. The monitoring device is, for example, the door control device 80 described above. The railway vehicle is, for example, the railway vehicle 1 described above. The door is, for example, the door 10 described above. The first member is, for example, the lock hole 32A described above. The second member is, for example, the lock pin 31 described above. The solenoid is, for example, the solenoid 34 described above. The locking device is, for example, the locking device 30 described above. Specifically, the monitoring device is configured to monitor the state of the locking device based on an electrical state observed when a first coil of the solenoid is energized. The first coil is, for example, the coil 34C described above.

In a monitoring method according to the first aspect of the present embodiment, the monitoring device is configured to monitor a state of the locking device, the locking device including a first member, a second member configured to achieve a locked state of a door of a railway vehicle by establishing a predetermined positional relation with the first member upon a movement toward the first member, and a solenoid configured to move the second member in a first direction away from the first member. Specifically, in the monitoring method according to the present aspect, the monitoring device is configured to monitor the state of the locking device based on an electrical state observed when a first coil of the solenoid is energized.

In a program according to the first aspect, an information processing device is caused to execute a process to monitor the state of the locking device, including the first member, the second member configured to achieve the locked state of the door of the railway vehicle by establishing the predetermined positional relation with the first member upon the movement toward the first member, and the solenoid configured to move the second member in the first direction away from the first member. The information processing device is, for example, the door control device 80 described above. Specifically, the program according to the present aspect is configured to cause the information processing device to monitor the state of the locking device based on an electrical state observed when a first coil of the solenoid is energized.

Thus, the monitoring device and the information processing device (hereinafter, “monitoring device, etc.”) can determine the state of the locking device, such as whether the plunger, the second member, and the like are in appropriate positions or moving appropriately, based on the electrical characteristics when the first coil of the solenoid is energized. Therefore, the monitoring device can appropriately monitor the state of the locking device.

In a second aspect of the present embodiment, according to the first aspect described above, the monitoring device may monitor the state of the locking device based on an electrical state observed when an alternating current is applied to the first coil.

Thus, the monitoring device can monitor the state of the locking device based on the electrical characteristics when the alternating current is applied to the first coil.

In a third aspect of the present embodiment, according to the second aspect, the monitoring device may estimate an inductance of the first coil based on a current value of the first coil observed when an alternating voltage is applied to the first coil, and monitor the state of the locking device based on an estimated value of the inductance.

Thus, the monitoring device or the like can monitor the state of the locking device by determining the position of the plunger and the position of the second member, for example, using the correlation between the inductance and the position of the plunger.

In a fourth aspect of the present embodiment, according to the second or third aspect described above, the locking device may perform an unlocking operation by energizing the first coil and moving a plunger in the first direction, thereby shifting the second member from a state in which the predetermined positional relation with the first member is established to a state in which the predetermined positional relation with the first member is not established. The plunger is, for example, the plunger 34B described above. After the unlocking operation of the locking device is completed, the monitoring device may monitor an unlocking state of the door by the locking device based on the electrical state observed when the alternating current is applied to the first coil.

Thus, the monitoring device or the like can monitor the unlocking state of the door by the locking device or the like based on the electrical characteristic when the alternating current is applied to the first coil.

In a fifth aspect of the present embodiment, according to any one of the second to the fourth aspects described above, a predetermined biasing force may act on the second member in a direction toward the first member. The predetermined biasing force is, for example, an elastic force of the biasing spring 33 described above. The locking device may perform an unlocking operation by energizing the first coil and moving a plunger in the first direction against the predetermined biasing force, thereby shifting the second member from a state in which the predetermined positional relation with the first member is established to a state in which the predetermined positional relation with the first member is not established, and a locking operation by moving the second member toward the first member with the predetermined biasing force, after shifting a locking state of the door from a state where locking is not possible to a state where locking is possible by moving the second member toward the first member in response to the door's closing movement. After the unlocking operation of the locking device is completed, the monitoring device may monitor the unlocking state of the door by the locking device based on the electrical state observed when the alternating current is applied to the first coil.

Thus, the monitoring device or the like can monitor the locking state of the door by the locking device based on the electrical characteristics when the alternating current is applied to the first coil.

In a sixth aspect of the present embodiment, according to the fifth aspect described above, the monitoring device may estimate an inductance of the first coil based on a current value of the first coil when an alternating voltage with a zero reference of voltage is applied to the first coil after the locking operation of the locking device is completed, and monitor the locking state of the door by the locking device based on an estimated value of the inductance.

Thus, for example, the monitoring device or the like can estimate the inductance of the first coil when alternating voltage is applied to the first coil so as not to move the plunger. Therefore, the monitoring device or the like can determine the position of the plunger based on the estimated value of the inductance by using, for example, the correlation between the inductance and the position of the plunger, and monitor whether the position of the plunger is appropriate or not.

In a seventh aspect of the present embodiment, according to the sixth aspect described above, in the unlocking operation, the locking device may shift the second member from the state in which the predetermined positional relation with the first member is established to the state in which the predetermined positional relation with the e first member is not established, by energizing the first coil and causing the second member or a third member connected to the second member to be abutted, and moving the plunger in the first direction to push the second member or the third member against the predetermined biasing force. The member connected to the second member is, for example, the vertical slider 35 described above.

Thus, the monitoring device or the like can monitor the state of the locking device in a form where the plunger of the solenoid and the second member are not connected.

In an eighth aspect of the present embodiment, according to the seventh aspect, the monitoring device may be configured to apply the alternating voltage with the zero reference of voltage applied to the first coil after the locking operation of the locking device is completed, subsequently, configured to apply a voltage to the first coil to stop the plunger being abutted against the second member or the third member, subsequently, configured to estimate the inductance of the first coil based on the current value of the first coil when the alternating voltage that keeps the plunger in a state of abutting the second member of the third member and not moving is applied to the first coil, and monitor the locking state of the door by the locking device based on an estimated value of the inductance.

Thus, the monitoring device or the like can estimate the inductance of the first coil when the plunger abuts against the second member and the like, for example. Therefore, the monitoring device or the like can indirectly monitor the position of the second member or the like by determining the position of the plunger based on the estimated value of inductance, for example, using the correlation between the inductance and the position of the plunger.

In a ninth aspect of the present embodiment, according to the seventh or eighth aspect, the monitoring device may apply the alternating voltage with the zero reference of voltage applied to the first coil after the locking operation of the locking device is completed, and subsequently, configured to monitor the locking state of the door by the locking device based on time series variation of a current of the first coil when a direct voltage that keeps the plunger in the state of abutting the second member or the third member and not moving in the first direction is applied to the first coil in a state in which the plunger is moving in the first direction without abutting the second member of the third member.

Thus, the monitoring device or the like can determine, for from example, the time series variation of the current of the first coil whether the current decreases due to the back electromotive force associated with the relatively large movement of the plunger, and monitor whether the position of the second member or the like based on the plunger is appropriate.

In a tenth aspect of the present embodiment, according to the second or third aspect, the solenoid may be a self-holding type including the first coil for moving a plunger in the first direction, and a second coil for moving the plunger in a second direction opposite to the first direction. The second coil is, for example, the coil 34D described above. The locking device may perform an unlocking operation by energizing the first coil and moving the plunger in the first direction, thereby shifting the second member from a state in which the predetermined positional relation first with the member is established to a state in which the predetermined positional relation with the first member is not established. After the unlocking operation of the locking device is completed, the monitoring device may monitor the unlocking state of the door by the locking device based on the electrical state observed when the alternating current is applied to the first coil or the second coil.

Thus, the monitoring device or the like can monitor the unlocking state of the locking device to which the self-holding type solenoid is applied.

In an eleventh aspect of the present embodiment, according to the second, third, or tenth aspect described above, the solenoid may be a self-holding type including the first coil for moving a plunger in the first direction, and a second coil for moving the plunger in a second direction opposite to the first direction. The locking device may perform a locking operation by moving the second member toward the first member by energizing the second coil and moving the plunger in the second direction, after shifting the locking state of the door from a state where locking is not possible to a state where locking is possible by moving the second member toward the first member in response to the door's closing movement. After an unlocking operation of the locking device is completed, the monitoring device may monitor the unlocking state of the door by the locking device based on the electrical state observed when the alternating current is applied to the first coil or the second coil.

Thus, the monitoring device or the like can monitor the locking state of the locking device to which the self-holding type solenoid is applied.

In a twelfth aspect of the present embodiment, according to the eleventh aspect, a predetermined biasing force may act on the second member in a direction toward the first member. In the locking operation, the locking device may move the second member toward the first member by an action of the predetermined biasing force by energizing the second coil and moving the plunger in the second direction away from the second member or a third member connected to the second member, after shifting the locking state of the door from the state where locking is not possible to the state where locking is possible by moving the second member toward the first member in response to the door's closing movement. After the unlocking operation of the locking device is completed, the monitoring device may monitor presence or absence of abnormality in a position of the plunger based on the electrical state observed when the alternating current is applied to the first coil or the second coil.

Thus, the monitoring device or the like can monitor the presence or absence of abnormality in the position of the plunger in the locked state of the locking device to which the self-holding solenoid is applied.

Further, in a thirteenth aspect according to the present embodiment, according to any one of the first to twelfth aspects, the monitoring device may monitor the state of the locking device based on an electrical state observed when a direct current is applied to the first coil.

Thus, the monitoring device or the like can monitor the state of the locking device based on the electrical characteristics when the direct current is applied to the first coil.

In a fourteenth aspect of the present embodiment, according to the thirteenth aspect, the monitoring device may monitor the state of the locking device based on a time series variation of a current of the first coil when a direct voltage is applied to the first coil.

Thus, the monitoring device or the like can determine, for example, whether or not the current decreases due to the back electromotive force accompanying the relatively large movement of the plunger from the time series variation of the current of the first coil, and monitor the movement state of the plunger or the like.

Further, the present invention is not limited to these embodiments, but various variations and modifications may be made without departing from the scope of the present invention.

What is claimed is:

1. A monitoring device for monitoring a state of a locking device, the locking device comprising:
a first member;
a second member configured to achieve a locked state of a door of a railway vehicle by establishing a predetermined positional relation with the first member upon a movement toward the first member; and
a solenoid configured to move the second member in a first direction away from the first member,
wherein the monitoring device is configured to monitor the state of the locking device based on an electrical state observed when a first coil of the solenoid is energized.

2. The monitoring device according to claim 1, configured to monitor the state of the locking device based on an electrical state observed when an alternating current is applied to the first coil.

3. The monitoring device according to claim 2, configured to estimate an inductance of the first coil based on a current value of the first coil observed when an alternating voltage is applied to the first coil, and monitor the state of the locking device based on an estimated value of the inductance.

4. The monitoring device according to claim 2, wherein:
the locking device is configured to perform an unlocking operation by energizing the first coil and moving a plunger in the first direction, thereby shifting the second member from a state in which the predetermined positional relation with the first member is established to a state in which the predetermined positional relation with the first member is not established; and
after the unlocking operation of the locking device is completed, the monitoring device is configured to monitor an unlocking state of the door by the locking device based on the electrical state observed when the alternating current is applied to the first coil.

5. The monitoring device according to claim 2, wherein:
a predetermined biasing force is configured to act on the second member in a direction toward the first member;
the locking device is configured to perform an unlocking operation by energizing the first coil and moving a plunger in the first direction against the predetermined biasing force, thereby shifting the second member from a state in which the predetermined positional relation with the first member is established to a state in which the predetermined positional relation with the first member is not established, and a locking operation by moving the second member toward the first member with the predetermined biasing force, after shifting a locking state of the door from a state where locking is not possible to a state where locking is possible by moving the second member toward the first member in response to the door's closing movement; and
after the unlocking operation of the locking device is completed, the monitoring device is configured to monitor the unlocking state of the door by the locking device based on the electrical state observed when the alternating current is applied to the first coil.

6. The monitoring device according to claim 5, configured to estimate an inductance of the first coil based on a current value of the first coil when an alternating voltage with a zero reference of voltage is applied to the first coil after the locking operation of the locking device is completed, and monitor the locking state of the door by the locking device based on an estimated value of the inductance.

7. The monitoring device according to claim 6, wherein in the unlocking operation, the locking device is configured to shift the second member from the state in which the predetermined positional relation with the first member is established to the state in which the predetermined positional relation with the first member is not established, by energizing the first coil and causing the second member or a third member connected to the second member to be abutted, and moving the plunger in the first direction to push the second member of the third member against the predetermined biasing force.

8. The monitoring device according to claim 7, configured to apply the alternating voltage with the zero reference of voltage applied to the first coil after the locking operation of the locking device is completed, subsequently, configured to apply a voltage to the first coil to stop the plunger being abutted against the second member of the third member, subsequently, configured to estimate the inductance of the first coil based on the current value of the first coil when the alternating voltage that keeps the plunger in a state of abutting the second member or the third member and not moving is applied to the first coil, and monitor the locking state of the door by the locking device based on an estimated value of the inductance.

9. The monitoring device according to claim 7, configured to apply the alternating voltage with the zero reference of voltage applied to the first coil after the locking operation of the locking device is completed, and subsequently, configured to monitor the locking state of the door by the locking device based on time series variation of a current of the first coil when a direct voltage that keeps the plunger in the state of abutting the second member or the third member and not moving in the first direction is applied to the first coil in a state in which the plunger is moving in the first direction without abutting the second member of the third member.

10. The monitoring device according to claim 2, wherein:
the solenoid is a self-holding type comprising the first coil for moving a plunger in the first direction, and a second coil for moving the plunger in a second direction opposite to the first direction;
the locking device is configured to perform an unlocking operation by energizing the first coil and moving the plunger in the first direction, thereby shifting the second member from a state in which the predetermined positional relation with the first member is established to a state in which the predetermined positional relation with the first member is not established; and
after the unlocking operation of the locking device is completed, the monitoring device is configured to monitor the unlocking state of the door by the locking device based on the electrical state observed when the alternating current is applied to the first coil or the second coil.

11. The monitoring device according to claim 2, wherein:
the solenoid is a self-holding type comprising the first coil for moving a plunger in the first direction, and a second coil for moving the plunger in a second direction opposite to the first direction;
the locking device is configured to perform a locking operation by moving the second member toward the first member by energizing the second coil and moving the plunger in the second direction, after shifting the locking state of the door from a state where locking is not possible to a state where locking is possible by moving the second member toward the first member in response to the door's closing movement; and
after an unlocking operation of the locking device is completed, the monitoring device is configured to monitor the unlocking state of the door by the locking device based on the electrical state observed when the alternating current is applied to the first coil or the second coil.

12. The monitoring device according to claim 11, wherein:
a predetermined biasing force is configured to act on the second member in a direction toward the first member;
in the locking operation, the locking device is configured to move the second member toward the first member by an action of the predetermined biasing force by energizing the second coil and moving the plunger in the second direction away from the second member or a third member connected to the second member, after shifting the locking state of the door from the state where locking is not possible to the state where locking is possible by moving the second member toward the first member in response to the door's closing movement; and
after the unlocking operation of the locking device is completed, the monitoring device is configured to monitor presence or absence of abnormality in a position of the plunger based on the electrical state observed when the alternating current is applied to the first coil or the second coil.

13. The monitoring device according to claim 1, configured to monitor the state of the locking device based on an electrical state observed when a direct current is applied to the first coil.

14. The monitoring device according to claim 13, configured to monitor the state of the locking device based on a time series variation of a current of the first coil when a direct voltage is applied to the first coil.

15. A monitoring method for monitoring a state of a locking device, the locking device comprising:
a first member;
a second member configured to achieve a locked state of a door of a railway vehicle by establishing a predetermined positional relation with the first member upon a movement toward the first member; and
a solenoid configured to move the second member in a first direction away from the first member,
wherein the monitoring method comprises monitoring the state of the locking device based on an electrical state observed when a first coil of the solenoid is energized.

16. A computer readable medium storing a program that causes an information processing device to execute a process to monitor a state of a locking device, the locking device comprising:
a first member;
a second member configured to achieve a locked state of a door of a railway vehicle by establishing a predetermined positional relation with the first member upon a movement toward the first member; and
a solenoid configured to move the second member in a first direction away from the first member,
wherein the program comprises causing the information processing device to monitor the state of the locking device based on an electrical state observed when a first coil of the solenoid is energized.
